(19) United States
(12) Patent Application Publication
(10) Pub. No.: US 2026/0113953 A1
(43) Pub. Date: Apr. 23, 2026

(54) FERROELECTRIC MEMORY DEVICE AND METHOD FOR MANUFACTURING THE SAME

(71) Applicant: Samsung Electronics Co., Ltd., Suwon-si (KR)

(72) Inventors: Keonhee PARK, Suwon-si (KR); Haewook JEONG, Suwon-si (KR)

(21) Appl. No.: 19/297,852

(22) Filed: Aug. 12, 2025

(30) Foreign Application Priority Data
Oct. 23, 2024 (KR) 10-2024-0145996

(51) Int. Cl. H10B 53/20; G11C 5/06; H10B 53/10; H10B 53/30; H10D 1/00; H10D 1/68

(52) U.S. Cl. CPC H10B 53/20; G11C 5/063; H10B 53/10; H10B 53/30; H10D 1/716; H10D 1/041

(57) ABSTRACT

A ferroelectric memory device and a method for manufacturing the ferroelectric memory device are provided. The ferroelectric memory device includes a substrate, and capacitors stacked on the substrate. Each of the capacitors includes a first electrode, a ferroelectric layer on the first electrode, and a second electrode on the ferroelectric layer, and the first electrode includes a flat portion and an upper protrusion on the flat portion. The flat portion has a first width in a first direction parallel to an upper surface of the substrate, and the upper protrusion has a second width smaller than the first width in the first direction.

### CROSS-REFERENCE TO RELATED APPLICATION(S)

This U.S. non-provisional patent application claims priority under 35 U.S.C. § 119 to Korean Patent Application No. 10-2024-0145996, filed on Oct. 23, 2024, the entire contents of which are hereby incorporated by reference.

### BACKGROUND

A semiconductor device is attracting attention as an important component in the electronics industry due to characteristics thereof such as miniaturization, multi-functionality, and/or low manufacturing cost. However, as the electronics industry becomes more advanced, a trend of high integration of the semiconductor device is intensifying. For the high integration of the semiconductor device, a line width of semiconductor device patterns is gradually being reduced. However, recent refining of the patterns requires new and/or expensive exposure technology, and the like, and thus the high integration of the semiconductor device gradually becomes more difficult. Accordingly, recently, much research on new integration technology is being carried out.

### SUMMARY

The present disclosure provides a ferroelectric memory device with improved electrical characteristics.

The present disclosure also provides a method for manufacturing the ferroelectric memory device.

An implementation of the present disclosure provides a ferroelectric memory device including a substrate, and capacitors stacked on the substrate, wherein each of the capacitors includes a first electrode, a ferroelectric layer on the first electrode, and a second electrode on the ferroelectric layer, the first electrode includes a flat portion and an upper protrusion on the flat portion, the flat portion has a first width in a first direction parallel to an upper surface of the substrate, and the upper protrusion has a second width smaller than the first width in the first direction.

In an implementation of the present disclosure, a ferroelectric memory device includes a substrate, a first electrode disposed on the substrate, a first ferroelectric layer on the first electrode, second electrodes and second ferroelectric layers alternately stacked on the first ferroelectric layer, and a third electrode located on an uppermost second ferroelectric layer, wherein each of the second electrodes includes a flat portion, an upper protrusion protruding from the center of the flat portion upward, and lower protrusions protruding from edges of the flat portion downward, the first electrode includes the upper protrusion and the flat portion, and the third electrode includes the flat portion and the lower protrusions.

In an implementation of the present disclosure, a ferroelectric memory device includes a substrate, bit lines disposed on the substrate, and extending in a first direction parallel to an upper surface of the substrate, an active pattern connected to one of the bit lines, and vertical to an upper surface of the substrate, a selection line adjacent to a lower side surface of the active pattern, and extending in a second direction, the second direction being parallel to an upper surface of the substrate, and crossing the first direction, word lines stacked on the selection line, and adjacent to upper side surfaces of the active pattern, capacitors stacked on the substrate beside the active pattern, and a plate line in contact with an upper surface of an uppermost capacitor, wherein each of the capacitors includes a first electrode, a ferroelectric layer on the first electrode, and a second electrode on the ferroelectric layer, the first electrode includes a flat portion and at least one upper protrusion protruding onto the flat portion.

In an implementation of the present disclosure, a method for manufacturing a ferroelectric memory device includes forming a lower layer on a substrate, forming, on the lower layer, a first preliminary stack by alternately stacking first sacrificial layers, second sacrificial layers, and third sacrificial layers, forming grooves exposing the lower layer by etching the first preliminary stack, and forming a second preliminary stack, the grooves extending in a first direction, and the second preliminary stack having a structure in which first sacrificial patterns, second sacrificial patterns and third sacrificial patterns are alternately stacked, partially removing side surface portions of the second sacrificial patterns by supplying a first etchant through the grooves, and thus partially exposing upper surfaces of the first sacrificial patterns and lower surfaces of the third sacrificial patterns, exposing upper surfaces of the second sacrificial patterns by supplying a second etchant through the grooves to remove third sacrificial patterns, forming first electrodes covering side surfaces and upper surfaces of the second sacrificial patterns by depositing a first conductive layer through the grooves, each of the first electrodes having a hollow region thereinside, exposing the hollow region and lower surfaces of the first electrodes by supplying a third etchant through the grooves to partially remove the first sacrificial patterns, covering surfaces of the first electrodes by depositing a ferroelectric layer through the grooves, removing the first sacrificial patterns by supplying the third etchant through the grooves, and forming second electrodes in positions in which the first sacrificial patterns are removed.

In the method, depositing the ferroelectric layer is performed in an area selective deposition process.

### BRIEF DESCRIPTION OF THE DRAWINGS

The accompanying drawings are included to provide a further understanding of the present disclosure, and are incorporated in and constitute a part of this specification. The drawings illustrate implementations of the present disclosure and, together with the description, serve to explain principles of the present disclosure. In the drawings:

FIG. 1 is a circuit diagram of a ferroelectric memory device according to implementations of the present disclosure;

FIG. 2 is a perspective view of a ferroelectric memory device according to implementations of the present disclosure;

FIG. 3 is a plan view of a ferroelectric memory device according to implementations of the present disclosure;

FIG. 4A is a cross-sectional view taken along line A-A′ of FIG. 3 according to implementations of the present disclosure;

FIG. 4B is a cross-sectional view taken along line B-B′ of FIG. 3 according to implementations of the present disclosure;

FIGS. 5A and 5B are enlarged diagrams of part ‘P1’ of FIG. 4B according to implementations of the present disclosure, and FIGS. 5C and 5D are perspective views of the first electrode according to implementations of the present disclosure;

FIGS. 6A to 6D are perspective views of a ferroelectric memory device according to implementations of the present disclosure;

FIGS. 7A, 8A, 9A, 10A, 11A, 12A and 18A are plan views sequentially illustrating processes of manufacturing capacitors of the ferroelectric memory device of FIG. 3;

FIGS. 7B, 8B, 9B, 11B, 12B, 13A, 14A, 15A, 16A, 17A, and 18B are cross-sectional views sequentially illustrating processes of manufacturing capacitors of the ferroelectric memory device of FIG. 4A; and

FIGS. 7C, 8C, 9C, 10B, 11C, 12C, 13B, 14B, 15B, 16B and 17B are cross-sectional views sequentially illustrating processes of manufacturing capacitors of the ferroelectric memory device of FIG. 4B.

### DETAILED DESCRIPTION

Hereinafter, implementations of the present disclosure will be described in more detail with reference to the accompanying drawings in order to specifically describe the present disclosure. In the present specification, ‘a word line’, ‘a bit line’, ‘a plate line’ and ‘a selection line’ may be respectively referred to as ‘a first conductive line’, ‘a second conductive line’, ‘a third conductive line’ and ‘a fourth conductive line’. In the present specification, terms representing sequence such as first or second are used so as to distinguish components doing the same/similar functions, and the terms may be changed according to a sequence in which the components are mentioned.

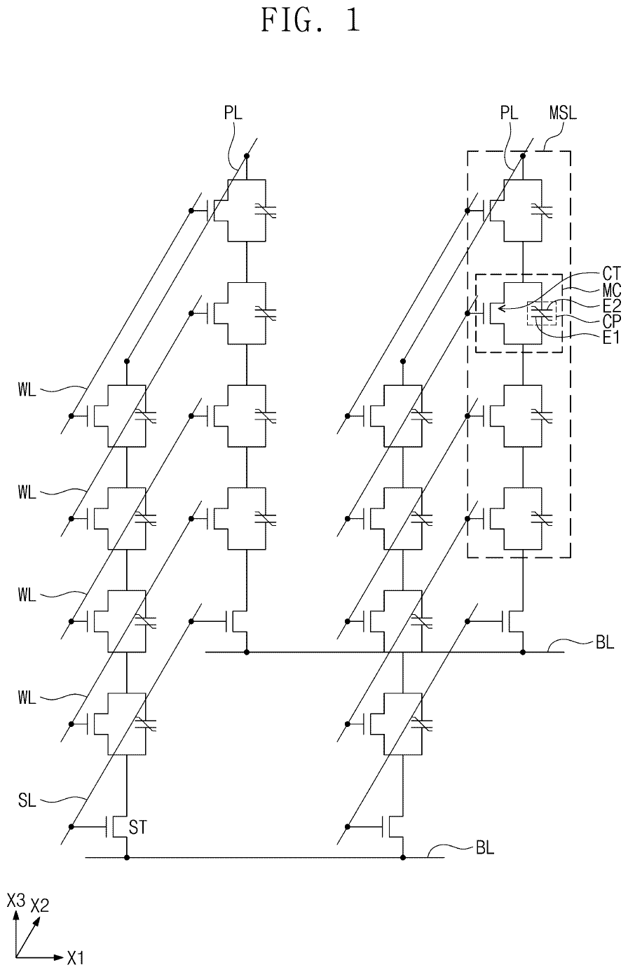

FIG. 1 is a circuit diagram of a ferroelectric memory device according to implementations of the present disclosure.

Referring to FIG. 1, the ferroelectric memory device according to the present implementation may include word lines WL, bit lines BL, plate lines PL, selection transistors ST, cell transistors CT and capacitors CP. The bit lines BL may extend in a first direction X1, and may be spaced apart from each other in a second direction X2 crossing the first direction X1. Chain memory cell strings MSL are connected to the bit lines BL. The chain memory cell strings MSL may extend in a third direction X3 crossing the first direction X1 and the second direction X2. The chain memory cell strings MSL may include a plurality of memory cells MC serially connected to each other along the third direction X3. Each of the memory cells MC includes one cell transistor CT and one capacitor CP parallelly connected to each other. The capacitor CP may be referred to as ‘a ferroelectric capacitor’.

One word line WL may extend in the second direction X2 to be connected to gates of a plurality of cell transistors CT, or may be gates of the plurality of cell transistors CT. The word line WL is provided in plurality. The word lines WL may extend in the second direction X2. The word lines WL may be spaced apart from each other in the first direction X1 and the third direction X3.

The selection transistors ST may be respectively disposed between the bit lines BL and the chain memory cell strings MSL. The plate lines PL may be connected to uppermost ends of the chain memory cell strings MSL, and may extend in the second direction X2. The plate lines PL may be spaced apart from each other in the first direction X1.

The one capacitor CP may include a first electrode E1, a second electrode E2 and a ferroelectric layer therebetween. The first electrode E1 may be connected to a first terminal (a source/drain region, dopant region or diffusion region) of the one cell transistor CT, and the second electrode E2 may be connected to a second terminal (a source/drain region, dopant region or diffusion region) of the one cell transistor CT. The ferroelectric layer may have a single-layered or multi-layered structure of at least one of a ferroelectric material or an anti-ferroelectric material. The ferroelectric memory device may be a three-dimensional chain ferroelectric random access memory (FeRAM).

The ferroelectric memory device may store information in the capacitors CP as remnant polarization. A logic value stored in the capacitors CP is changed according to polarization of the ferroelectric dielectric layer. A voltage greater than a switching voltage (a coercive voltage) needs to be applied to the first and second electrodes E1 and E2 so as to change the polarization of the ferroelectric dielectric layer. A capacitor may provide an involatile memory cell by maintaining the polarization state even after a power is removed.

The electrodes E1 and E2 of a pair of capacitors CP adjacent to each other among the capacitors CP may be connected to each other. For example, the second electrode E2 of one capacitor CP may be connected to the first electrode E1 of the capacitor CP located thereon.

When one chain memory cell string MSL is waiting or is not selected, a selection line SL connected to the one chain memory cell string MSL may be inactive, the selection transistor ST may be in an off state, and the word lines WL may be active, and thus the cell transistors CT may be all turned on to be conductive. In this case, 0 V may be applied to all of the plate line PL and the bit line BL connected to the one chain memory cell string MSL. In this case, the capacitors CP of the one chain memory cell string MSL may be short. Accordingly, an original data, that is, “0” or “1” may be maintained by protecting the data stored in each of the memory cells MC.

In order to retrieve or read information from one memory cell MC among the memory cells MC, or program information to the one memory cell MC among the memory cells MC, the selection line SL connected to the one chain memory cell string MSL to which the one memory cell MC belongs is active, the selection transistor ST is in an on state, a first voltage is applied to the bit line BL, and a second voltage is applied to the plate line. The cell transistors CT of other memory cells MC in the one chain memory cell string MSL except for the one memory cell MC are turned on. In addition, the cell transistor CT of the one memory cell MC may be turned off by inactivating the word line WL connected to the one memory cell MC to be non-conductive. Accordingly, electric field may be generated in the capacitor CP of the one memory cell MC. A polarization state of the ferroelectric layer of the capacitor CP of the one memory cell MC may be switched or maintained by a difference between the first voltage and the second voltage.

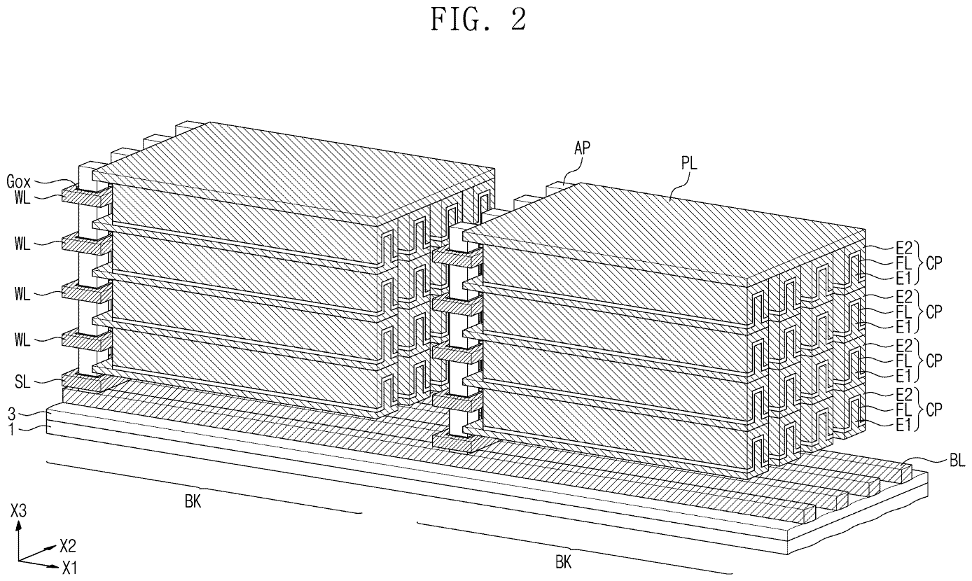

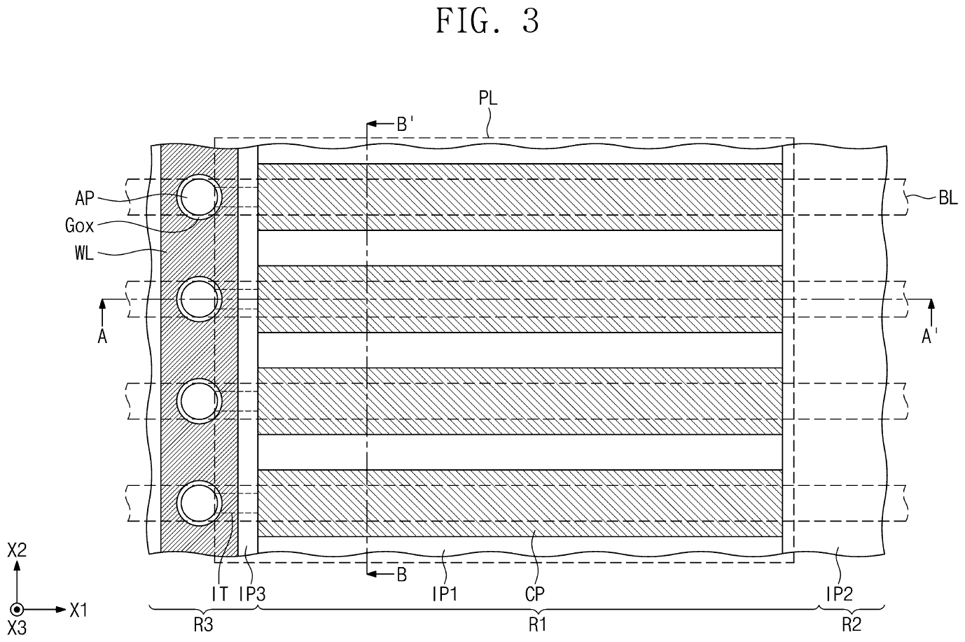

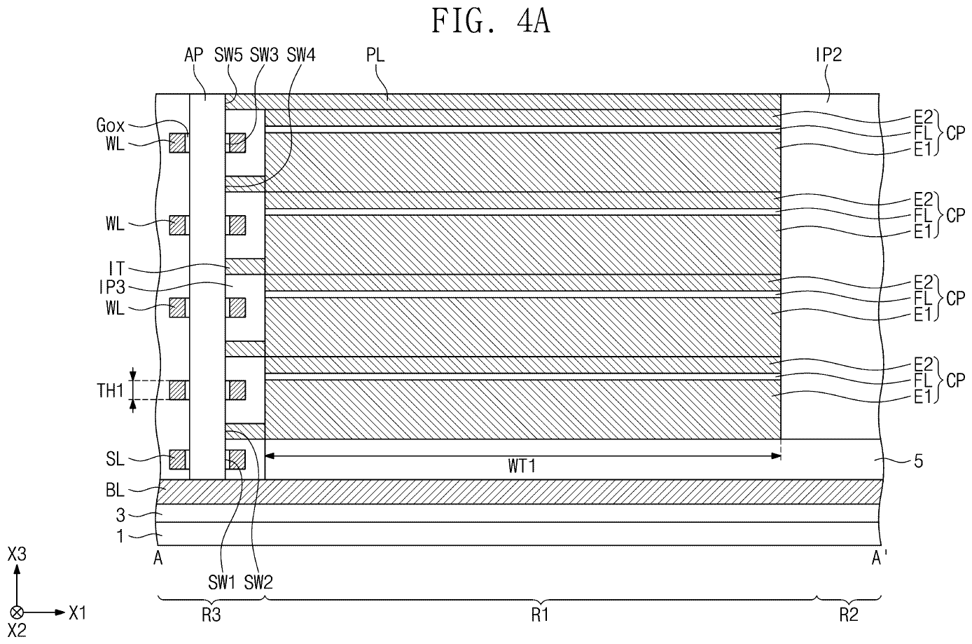

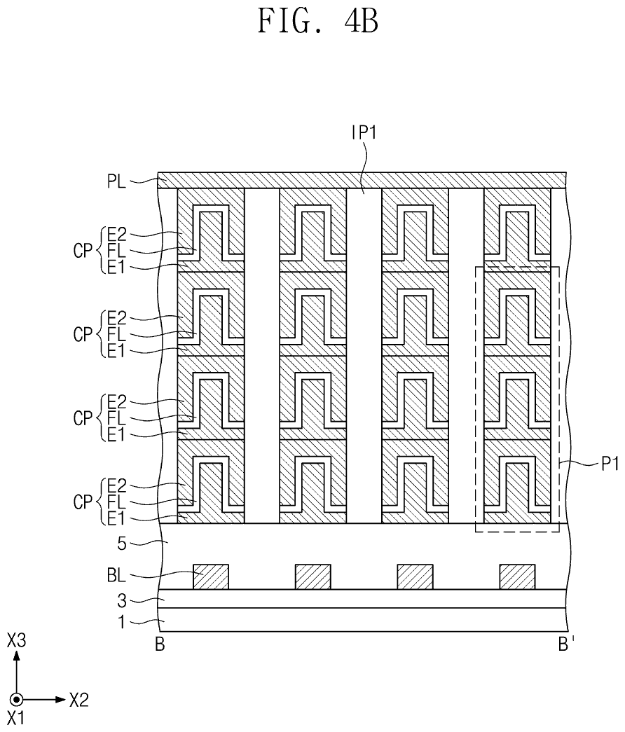

FIG. 2 is a perspective view of a ferroelectric memory device according to implementations of the present disclosure. FIG. 3 is a plan view of the ferroelectric memory device according to implementations of the present disclosure. FIG. 4A is a cross-sectional view taken along line A-A′ of FIG. 3 according to implementations of the present disclosure. FIG. 4B is a cross-sectional view taken along line B-B′ of FIG. 3 according to implementations of the present disclosure.

Referring to FIGS. 2, 3, 4A and 4B, a first lower insulating layer 3 is disposed on a substrate 1. The substrate 1 may be composed of a semiconductor material such as single-crystalline silicon, or an insulating material, or may be a silicon-on-insulator (SOI) substrate. The substrate 1 may include blocking regions BK parallelly disposed along the first direction X1. FIG. 3 illustrates a plan view of the ferroelectric memory device disposed on one blocking region BK. Each of the blocking regions BK includes first to third regions R1, R2 and R3. The first region R1 may be located between the second region R2 and the third region R3. The first lower insulating layer 3 may have a single-layered or multi-layered structure of an insulating material such as silicon oxide, silicon nitride, or silicon oxynitride.

Although not shown, a peripheral circuit structure may be disposed on the substrate 1. The peripheral circuit structure may include peripheral transistors and peripheral wires, and may include circuits applying a voltage to the word lines WL, the bit lines BL, the selection lines SL and the plate lines PL, or sensing an electrical signal. The peripheral circuit structure may be covered by the first lower insulating layer 3.

The bit lines BL are disposed on the first lower insulating layer 3. The bit lines BL may extend in the first direction X1, and may be spaced apart from each other in the second direction X2. The bit lines BL may be composed of a conductive material such as polysilicon doped with an impurity, tungsten or aluminum.

The bit lines BL may be covered by a second lower insulating layer 5. The second lower insulating layer 5 may have a single-layered or multi-layered structure of an insulating material such as silicon oxide, silicon nitride or silicon oxynitride.

Active patterns AP are disposed on the bit lines BL in the third region R3. The active patterns AP may extend in the third direction X3 vertical to an upper surface of the substrate 1. The active patterns AP may be composed of a single-crystalline silicon or polysilicon. The active patterns AP may be a circle, an ellipsoid, or a rectangle on a plan view. The active patterns AP may be two-dimensionally arranged along the first direction X1 and the second direction X2. The active pattern AP may be surrounded by a third separation insulating pattern IP3. The selection line SL and the word lines WL may be disposed in the third separation insulating pattern IP3. Each of the active patterns AP may have first to fifth side surfaces SW1 to SW5 vertically aligned with each other.

The selection line SL may be adjacent to the first side surface SW1 of the active pattern AP. The first side surface SW1 may be adjacent to a lower end of the active pattern AP. The selection line SL may extend along the second direction X2, and may surround the first side surfaces SW1 of the active patterns AP. The selection line SL may include a conductive material such as tungsten, aluminum or copper. A gate insulating layer Gox may be interposed between the selection line SL and the active pattern AP. The gate insulating layer Gox may have a single-layered or multi-layered structure of at least one of silicon oxide, silicon nitride, silicon oxynitride, or metal oxide.

The word lines WL are stacked on the selection line SL in the third direction X3. The word lines WL may be spaced apart from each other in the third direction X3. The word lines WL may include a conductive material such as tungsten, aluminum, or copper. The word lines WL may be adjacent to the third side surfaces SW3 of the active pattern AP. The word lines WL may surround the third side surfaces SW3 of the active pattern AP. The word lines WL may have a gate-all-around (GAA) shape. The gate insulating layer Gox may be interposed between the word lines WL and the active pattern AP.

The active pattern AP has the second side surface SW2 between the selection line SL and a lowermost word line WL. The active pattern AP has the fourth side surfaces SW4 between the word lines WL. The active pattern AP has the fifth side surface SW5 located an uppermost end thereof.

Connection wires IT may be disposed in the third separation insulating pattern IP3. The connection wires IT may be in contact with the second side surface SW2 and the fourth side surfaces SW4, respectively. The connection wires IT may be spaced apart from the selection line SL and the word lines WL. The connection wires IT may be composed of a conductive material.

The capacitors CP may be stacked on the second lower insulating layer 5. The capacitors CP are located on the first region R1. Each of the capacitors CP includes the first electrode E1, a ferroelectric layer FL and the second electrode E2 sequentially stacked. At least one of the first electrode E1, the second electrode E2 or the ferroelectric layer FL may have a first width WT1 in the first direction X1.

The first electrode E1 and the second electrode E2 may include a conductive material such as tungsten, aluminum or titanium. The ferroelectric layer FL may have a single-layered or multi-layered structure of at least one of a ferroelectric material or an anti-ferroelectric material. The ferroelectric material may be at least one of HfO₂, ZrO₂, HfₓZr₁₋ₓO₂, BaTiO₃, SrTiO₃, or SrₓBa₁₋ₓTiO₃, the anti-ferroelectric material may be at least one of ZrO₂, Hf_{y}Zr_{1-y}O₂, PbZrO₃, or AgNbO₃, the x may be at least about 0.5, and the y may be less than about 0.5. The ferroelectric layer FL may be referred to as ‘a dielectric layer’.

The first electrode E1 may be connected to the connection wire IT. Alternatively, the connection wire IT may be omitted, and the first electrode E1 may extend and penetrate the third separation insulating pattern IP3 to be in contact with the second side surface SW2 or the fourth side surface SW4 of the active pattern AP.

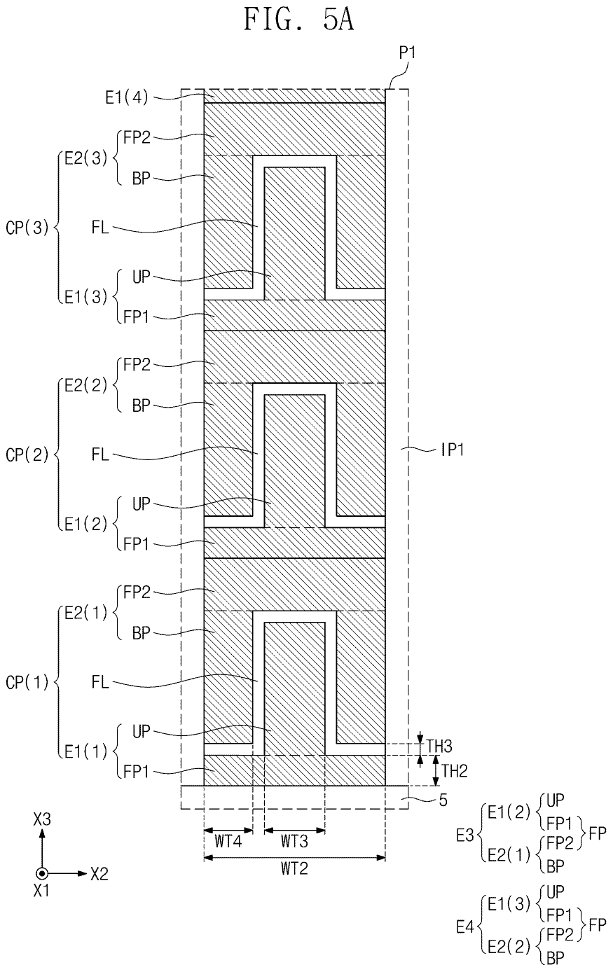

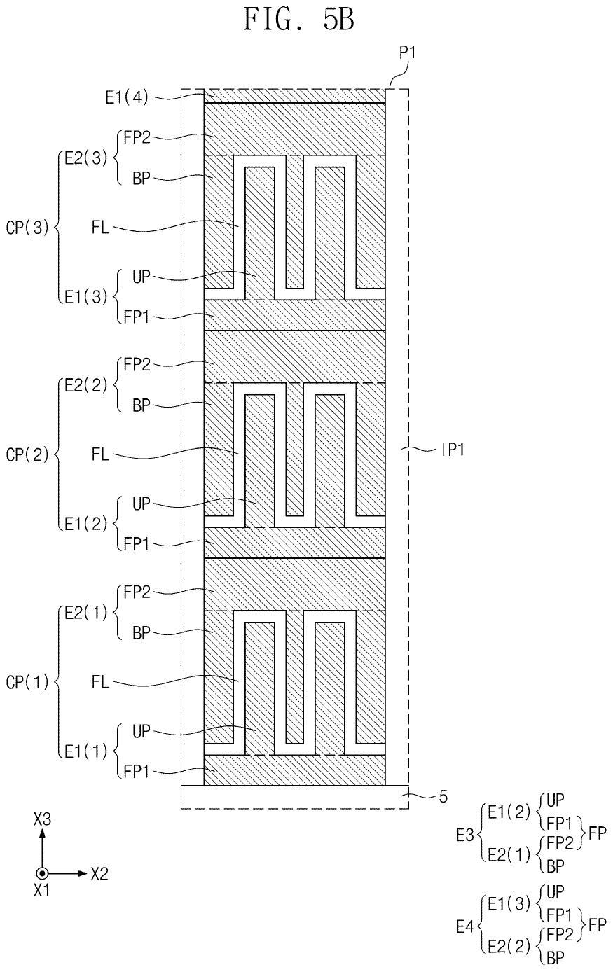

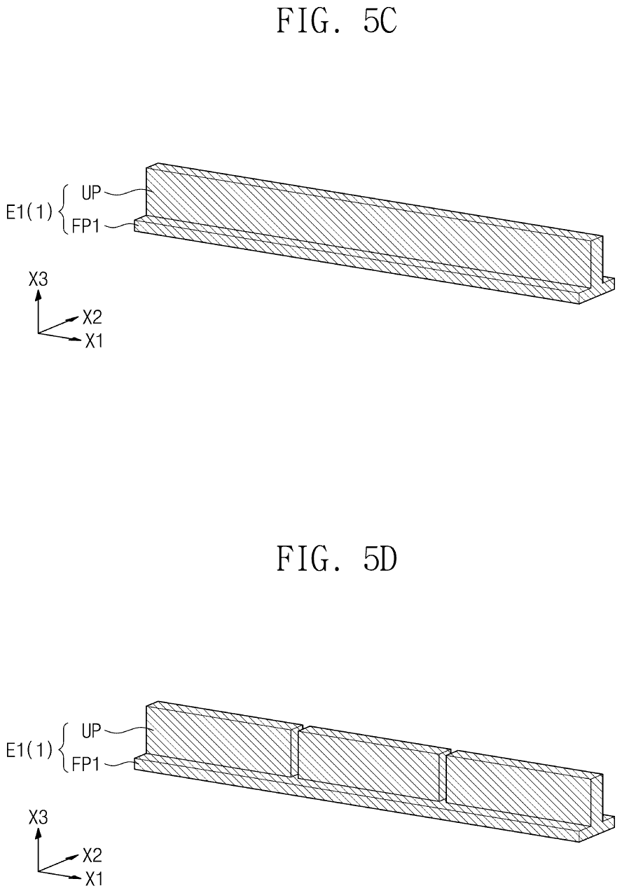

FIGS. 5A and 5B are enlarged diagrams of part ‘P1’ of FIG. 4B according to implementations of the present disclosure.

Referring to FIGS. 5A and 5B, the first electrode E1 may include a first flat portion FP1 and an upper protrusion (or referred to as an upper protrusion portion) UP disposed thereon. The first flat portion FP1 and the upper protrusion UP may not have a boundary surface therebetween, and may be integrally composed. The first flat portion FP1 may have a second width WT2 in the second direction X2. The second width WT2 may be smaller than the first width WT1 of FIG. 4A. The upper protrusion UP may have a third width WT3 smaller than the second width WT2 in the second direction X2. The upper protrusion UP may be provided in one like FIG. 5A, or in plurality like FIG. 5B. The ferroelectric layer FL may cover an upper surface and a side surface of the upper protrusion UP, and an upper surface of the first flat portion FP1. An upper surface of the first electrode E1, a lower surface of the second electrode E2, and upper and lower surfaces of the ferroelectric layer FL may have an irregularity structure.

FIGS. 5C and 5D are perspective views of the first electrode according to implementations of the present disclosure.

The upper protrusion UP may be continuous along the first direction X1 like FIG. 5C. Alternatively, the upper protrusion UP may be cut at least once in the first direction X1 like FIG. 5D. Accordingly, the upper protrusion UP may be provided in plurality like FIG. 5D.

The second electrode E2 may include a second flat portion FP2 and lower protrusions (or referred to as lower protrusion portions) BP disposed thereunder. The second flat portion FP2 and the lower protrusions BP may not have a boundary surface therebetween, and may be integrally composed. The second flat portion FP2 may have the second width WT2 in the second direction X2. Each of the lower protrusions BP may have a fourth width WT4 smaller than the second width WT2 in the second direction X2.

Each of the word lines WL may have a first thickness TH1 in the third direction X3. The first flat portion FP1 may have a second thickness TH2. The ferroelectric layer FL may have a third thickness TH3. The third thickness TH3 may be smaller than at least one of the first thickness TH1 or the second thickness TH2.

The electrodes E1 and E2 of adjacent capacitors CP among the capacitors CP may be in contact with each other. For example, a second electrode E2(1) of a first capacitor CP(1) may be in contact with a first electrode E1(2) of a second capacitor CP(2) located thereon. When the first electrode E1(2) and the second electrode E2(1) are composed of the same material, a boundary surface therebetween may not be inspected. Accordingly, the first electrode E1(2) and the second electrode E2(1) may be integrally seen. The first electrode E1(2) and the second electrode E2(1) in contact with each other and integrally composed may constitute a third electrode E3.

Likewise, a second electrode E2(2) of the second capacitor CP(2) may be in contact with a first electrode E1(3) of a third capacitor CP(3) located thereon. When the second electrode E2(2) and the first electrode E1(3) are composed of the same material, a boundary surface therebetween may not be inspected. Accordingly, the second electrode E2(2) and the first electrode E1(3) may be integrally seen. The second electrode E2(2) and the first electrode E1(3) in contact with each other and integrally composed may constitute a fourth electrode E4. A second electrode E2(3) of the third capacitor CP(3) and a first electrode E1(4) of the capacitor CP thereon may be in contact with each other and may be integrally composed.

Referring to FIGS. 4A, 4B, 5A and 5B, a first electrode E1(1), the ferroelectric layer FL, the third electrode E3, the ferroelectric layer FL and the fourth electrode E4 may be sequentially stacked on the first region R1. Each of the third electrode E3 and the fourth electrode E4 may include the flat portion FP, the upper protrusion UP protruding thereon, and the lower protrusion BP protruding thereunder. The flat portion FP may include the first flat portion FP1 and the second flat portion FP2.

The capacitors CP may vertically overlap the bit lines BL. Side surfaces of the capacitors CP may be aligned with each other. The capacitors CP may be spaced apart from each other in the second direction X2. A first separation insulating pattern IP1 may be interposed between the capacitors CP. The first separation insulating pattern IP1 may be long in the first direction X1 on a plan view. The first separation insulating pattern IP1 may be in contact with the second lower insulating layer 5.

The plate line PL may be in contact with the second electrodes E2 of uppermost capacitors CP on one blocking region BK. The plate line PL may extend in the second direction X2. The plate line PL may be in contact with the fifth side surface SW5 of the active patterns AP.

A second separation insulating pattern IP2 is disposed on the second region R2. The second separation insulating pattern IP2 may be in contact with end portions of the capacitors CP, and an upper surface of the second lower insulating layer 5.

In the ferroelectric memory device according to the present disclosure, since the electrodes E1 and E2 of the capacitors CP have protrusions UP and BP, capacitance of the capacitors CP may increase. Accordingly, horizontal lengths (the first width WT1 of FIG. 4A) of the capacitors CP may be relatively reduced. Integration of the ferroelectric memory device may be improved. In addition, since the third thickness TH3 of the ferroelectric layer FL is small (TH3<TH1), an operation voltage may be reduced, and a switching speed may be improved. Accordingly, reliability and electrical characteristics of the ferroelectric memory device may be improved.

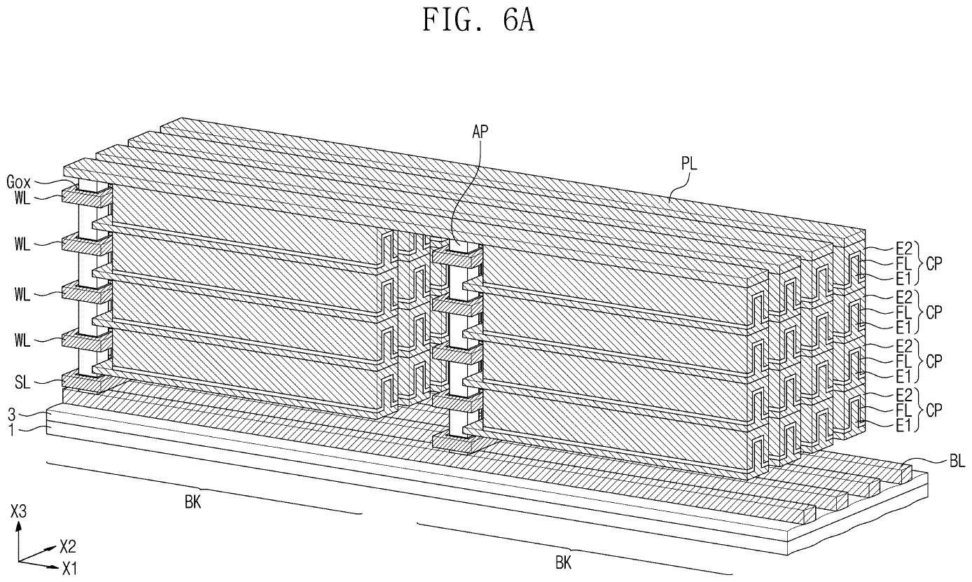

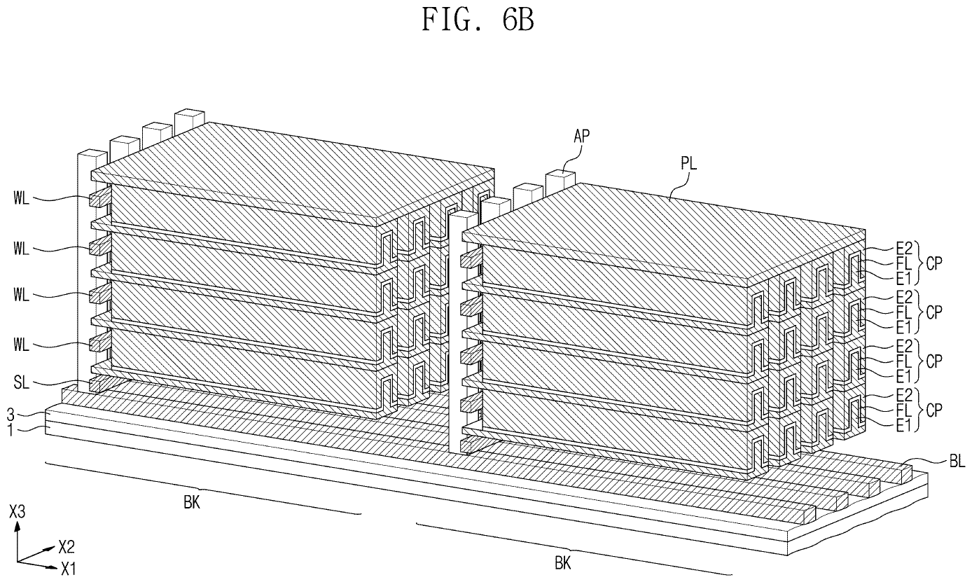

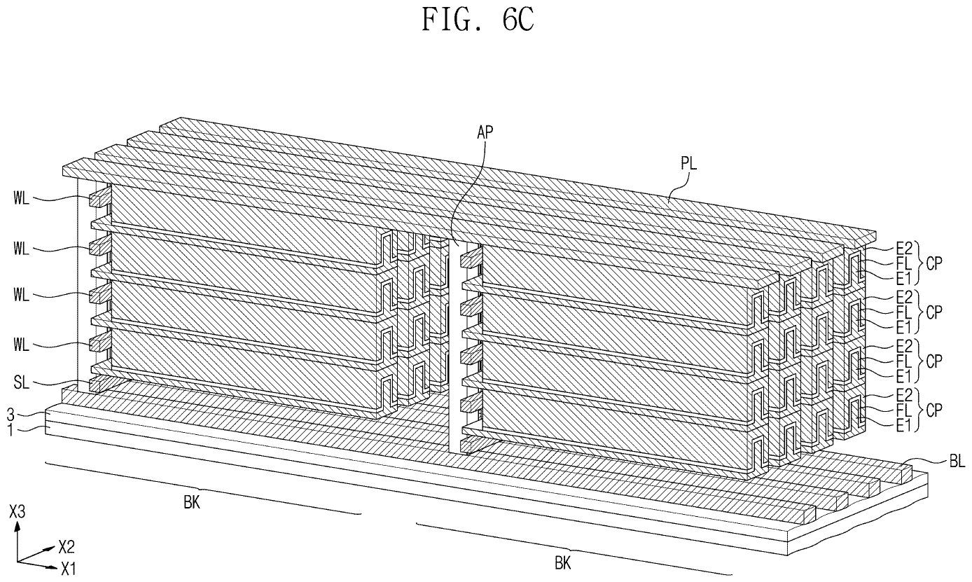

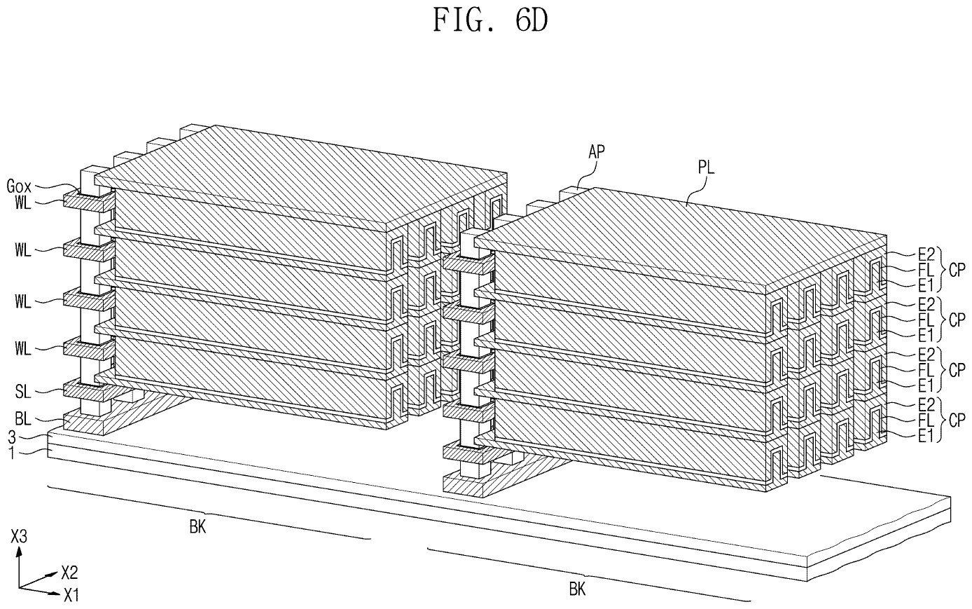

FIGS. 6A to 6D are perspective views of the ferroelectric memory device according to implementations of the present disclosure.

The plate lines PL may extend in the first direction X1 like FIG. 6A, and may be spaced apart from each other in the second direction X2. A structure except for those may be the same as what is described with reference to FIG. 2.

The word lines WL and the selection line SL may not surround a side surface of the active pattern AP, and may be adjacent to only one side surface of the active pattern AP like FIG. 6B. According to another implementation, the word lines WL and the selection line SL may be adjacent to both side surfaces of the active pattern AP. A structure except for those may be the same as what is described with reference to FIG. 2.

Alternatively, the plate lines PL may extend in the first direction X1 like FIG. 6C, and may be spaced apart from each other in the second direction X2. In addition, the word lines WL and the selection line SL may not surround the side surface of the active pattern AP, and may be adjacent to only one side surface of the active pattern AP like FIG. 6C.

Alternatively, the bit lines BL may extend in the second direction X2 like FIG. 6D, and may be spaced apart from each other in the first direction X1. The bit lines BL may be parallel to the word lines WL.

Next, processes of manufacturing capacitors in a ferroelectric memory device according to implementations of the present disclosure will be described.

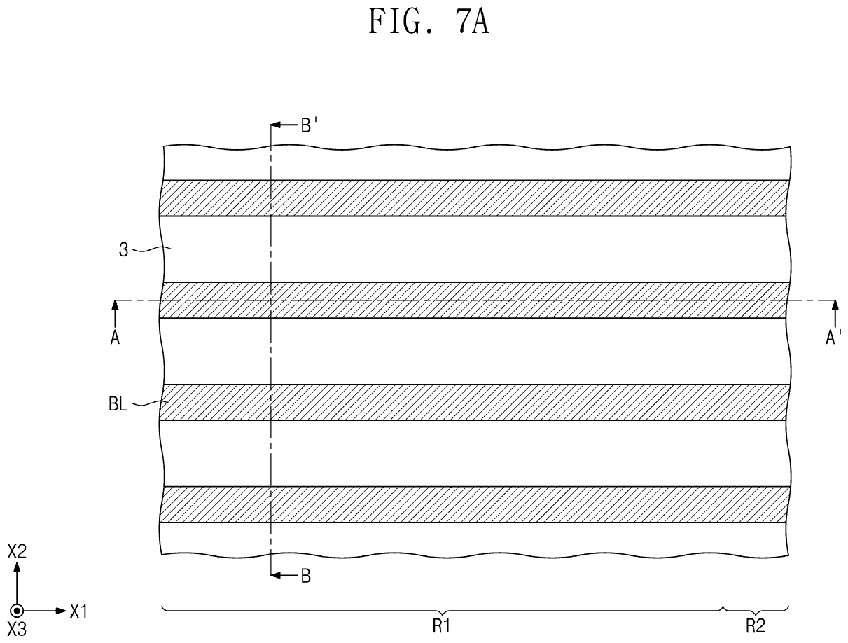

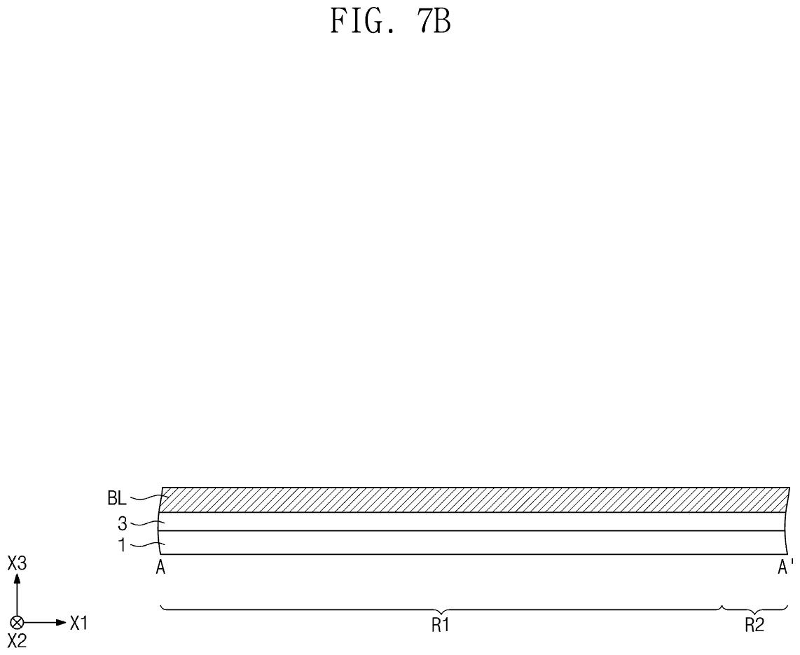

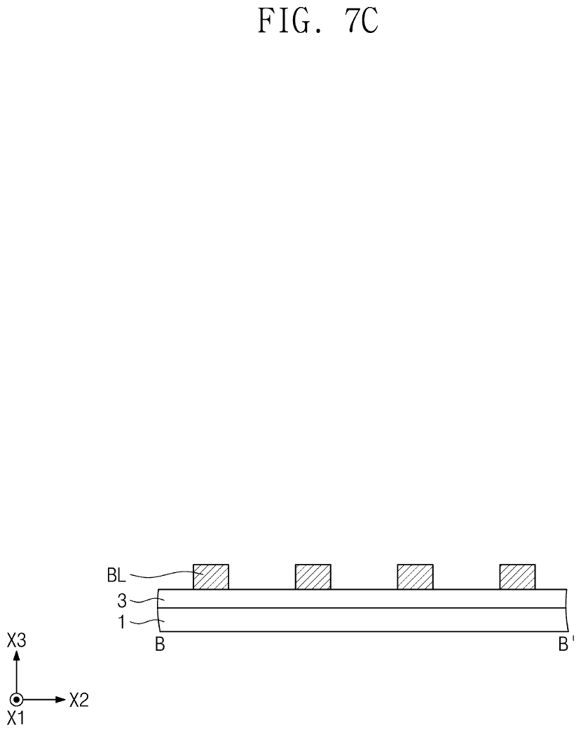

FIGS. 7A, 8A, 9A, 10A, 11A, 12A and 18A are plan views sequentially illustrating processes of manufacturing capacitors of the ferroelectric memory device of FIG. 3. FIGS. 7B, 8B, 9B, 11B, 12B, 13A, 14A, 15A, 16A, 17A, and 18B are cross-sectional views sequentially illustrating processes of manufacturing capacitors of the ferroelectric memory device of FIG. 4A. FIGS. 7C, 8C, 9C, 10B, 11C, 12C, 13B, 14B, 15B, 16B and 17B are cross-sectional views sequentially illustrating processes of manufacturing capacitors of the ferroelectric memory device of FIG. 4B. FIGS. 7B, 8B, 9B, 11B, 12B and 18B are cross-sectional views taken along line A-A′ of FIGS. 7A, 8A, 9A, 11A, 12A and 18A. FIGS. 7C, 8C, 9C, 10B, 11C and 12C are cross-sectional views taken along line B-B′ of FIGS. 7A, 8A, 9A, 10A, 11A and 12A.

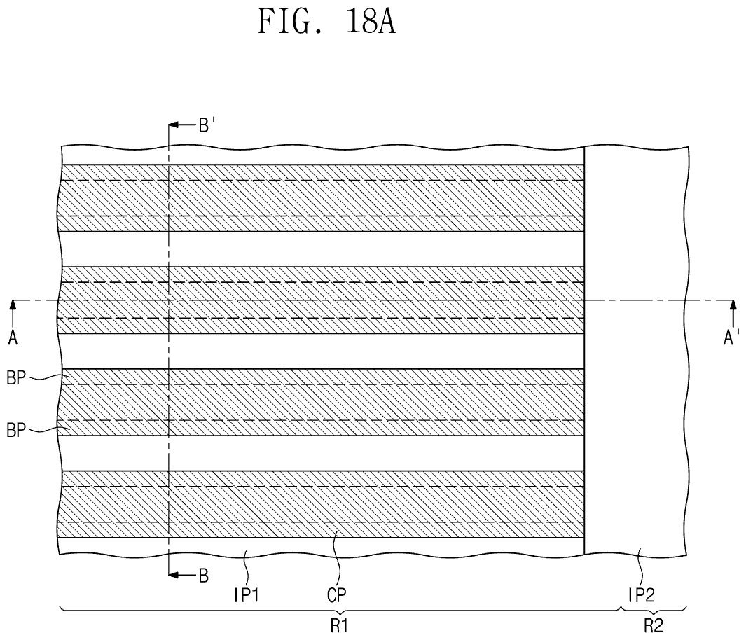

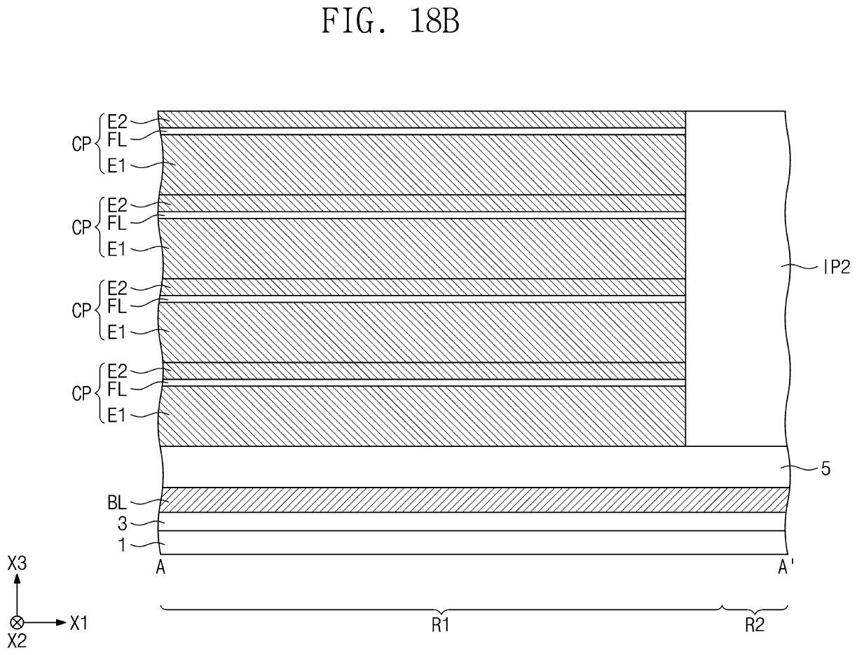

Referring to FIGS. 3, 4A and 7A to 7C, a first lower insulating layer 3 is formed on a substrate 1. The substrate 1 includes a first region R1 and a second region R2 parallelly disposed in the first direction X1. The substrate 1 may include a third region R3 like FIGS. 3 and 4A. Active patterns AP, connection wires IT, a third separation insulating pattern IP3, a selection line SL and word lines WL may be formed on the third region R3. The active patterns AP, the connection wires IT, the third separation insulating pattern IP3, the selection line SL, and the word lines WL may be formed before forming the first lower insulating layer 3 of FIGS. 7A to 7C, or after forming a second separation insulating pattern IP2 of FIGS. 18A and 18B.

Bit lines BL are formed by stacking and patterning a conductive layer on the first lower insulating layer 3. The bit lines BL may be formed on the first to third regions R1, R2 and R3. The bit lines BL may be formed so as to extend in the first direction X1 and to be spaced apart from each other in the second direction X2.

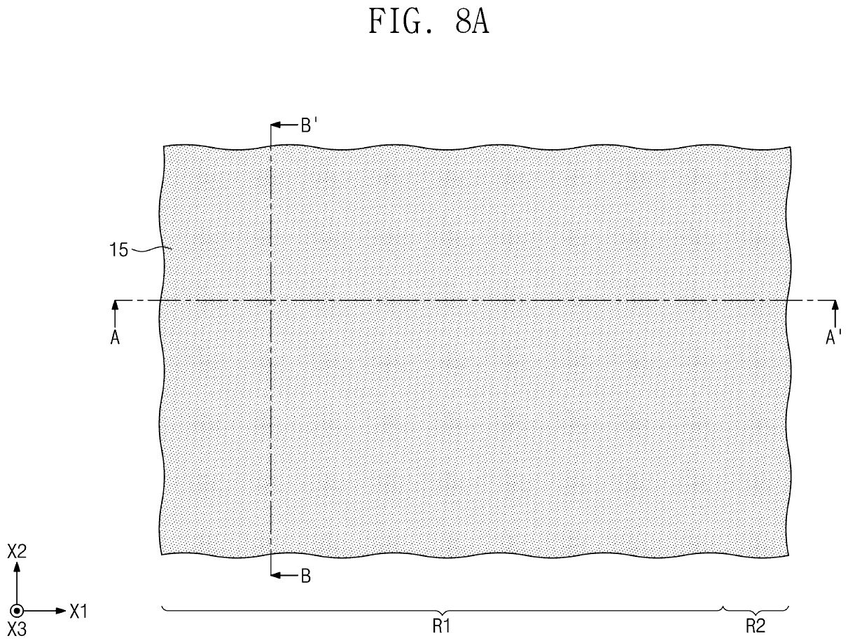

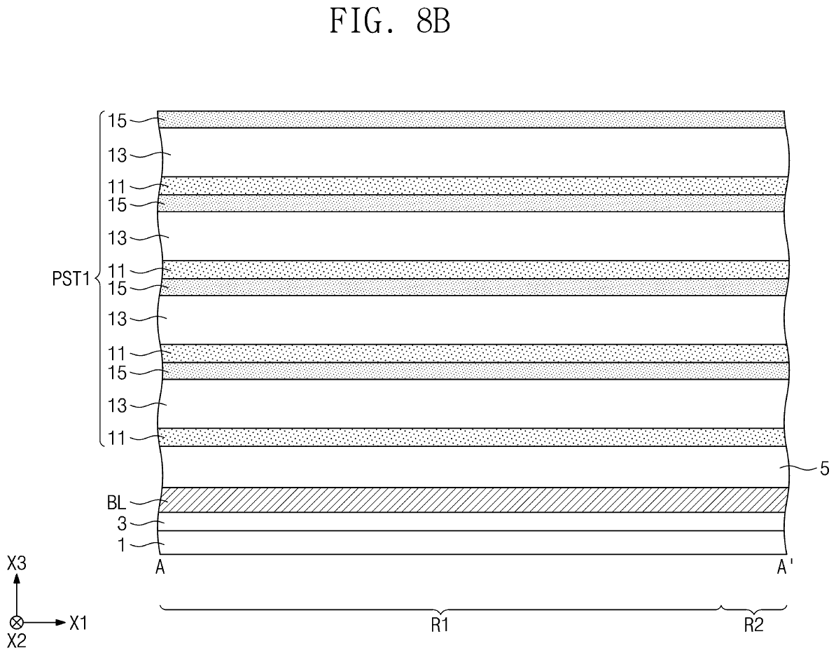

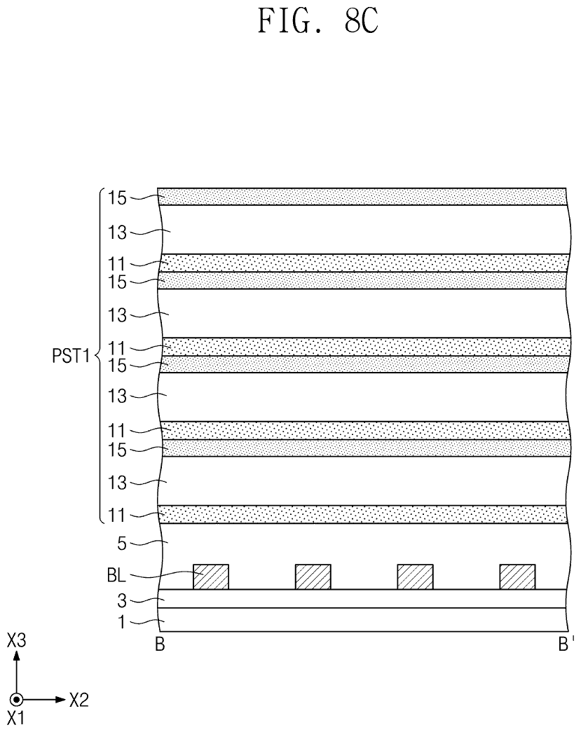

Referring to FIGS. 8A to 8C, a second lower insulating layer 5 covering the bit lines BL is formed. A first preliminary stack structure PST1 is formed by alternately repeatedly stacking first sacrificial layers 11, second sacrificial layers 13, and third sacrificial layers 15 on the second lower insulating layer 5. The first to third sacrificial layers 11, 13 and 15 may be formed of materials having etching selectivity for each other. For example, the first sacrificial layers 11 may be formed of polysilicon. The second sacrificial layers 13 may be formed of silicon oxide. The third sacrificial layers 15 may be formed of silicon-germanium, silicon nitride, SiON or SiCN.

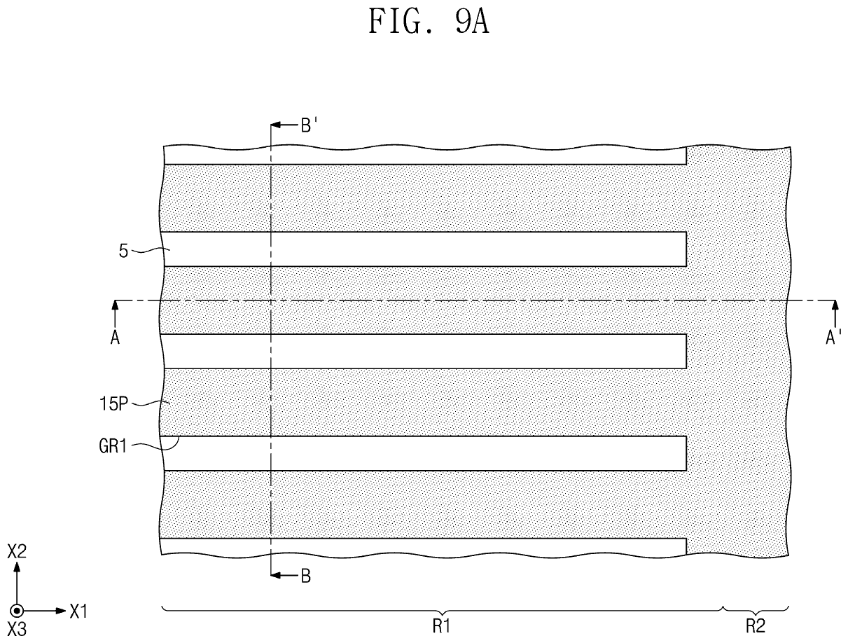

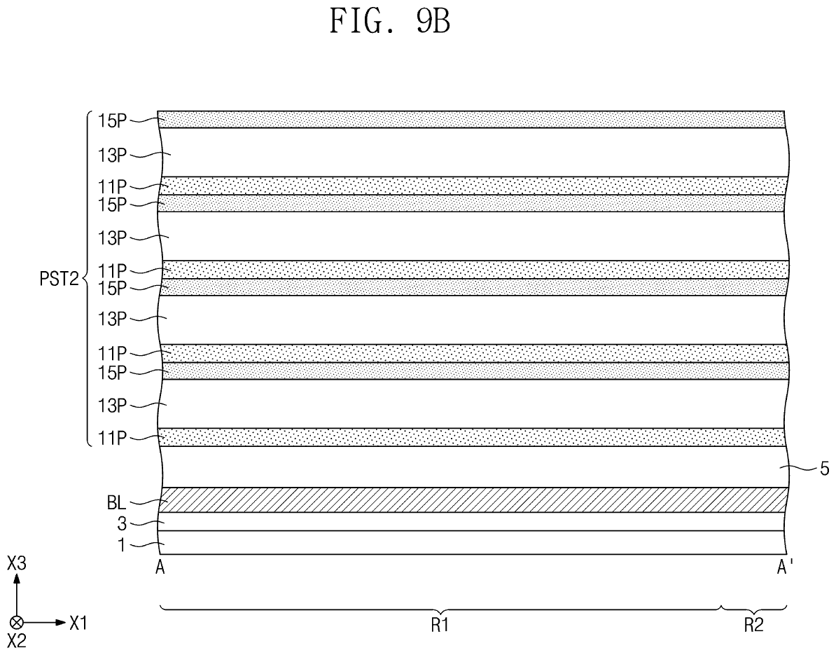

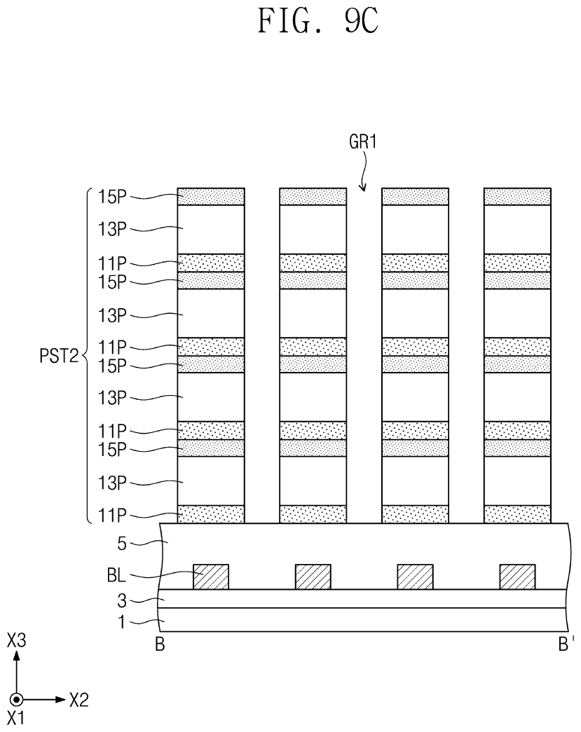

Referring to FIGS. 9A to 9C, first grooves GR1 exposing an upper surface of the second lower insulating layer 5 are formed by etching the first preliminary stack structure PST1. In this case, first to third sacrificial patterns 11P, 13P and 15P may be formed by etching the first to third sacrificial layers 11, 13 and 15 of the first preliminary stack structure PST1.

The first grooves GR1 may be formed on the first region R1, and may not be formed on the second region R2. The first grooves GR1 may be formed so as to be long in the first direction X1 and to be spaced apart from each other in the second direction X2. The first grooves GR1 may not overlap the bit lines BL. The first preliminary stack structure PST1 may become a second preliminary stack structure PST2 including the first to third sacrificial patterns 11P, 13P and 15P by forming the first grooves GR1.

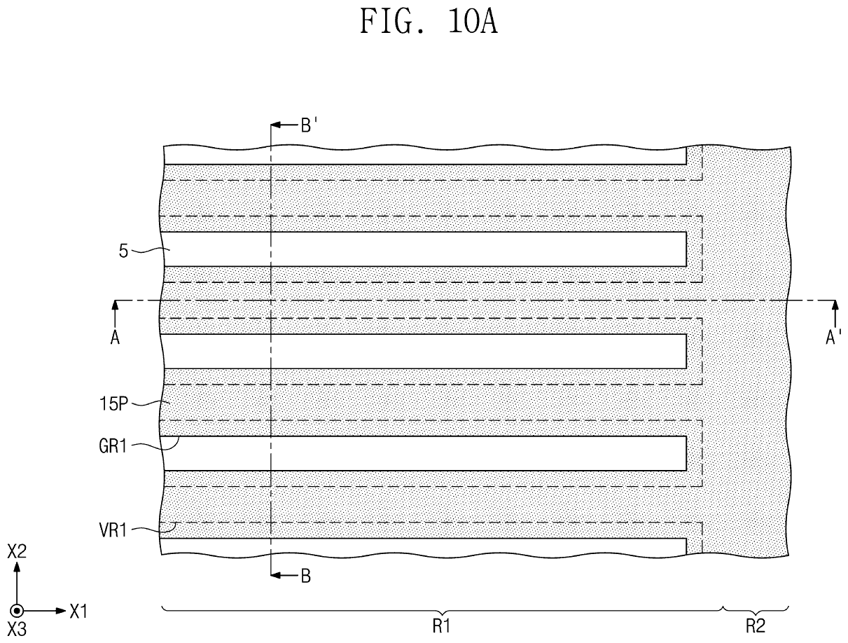

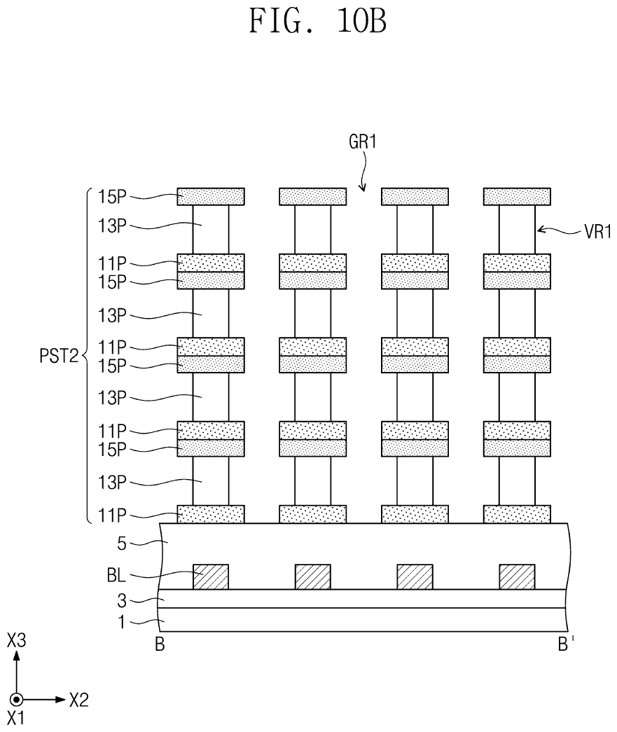

A cross-section taken along line A-A′ of FIG. 10A may be the same as FIG. 9B. Referring to FIGS. 9B, 10A and 10B, an isotropic etching process is performed by supplying a first etchant through the first grooves GR1. Accordingly, side surface portions of the second sacrificial patterns 13P of the second preliminary stack structure PST2 may be partially removed, and first empty spaces VR1 may be formed. Upper surfaces of the first sacrificial patterns 11P and lower surfaces of the third sacrificial patterns 15P may be partially exposed by the first empty spaces VR1. The second sacrificial patterns 13P may have narrower widths in the second direction X2 than the first sacrificial patterns 11P and the third sacrificial patterns 15P.

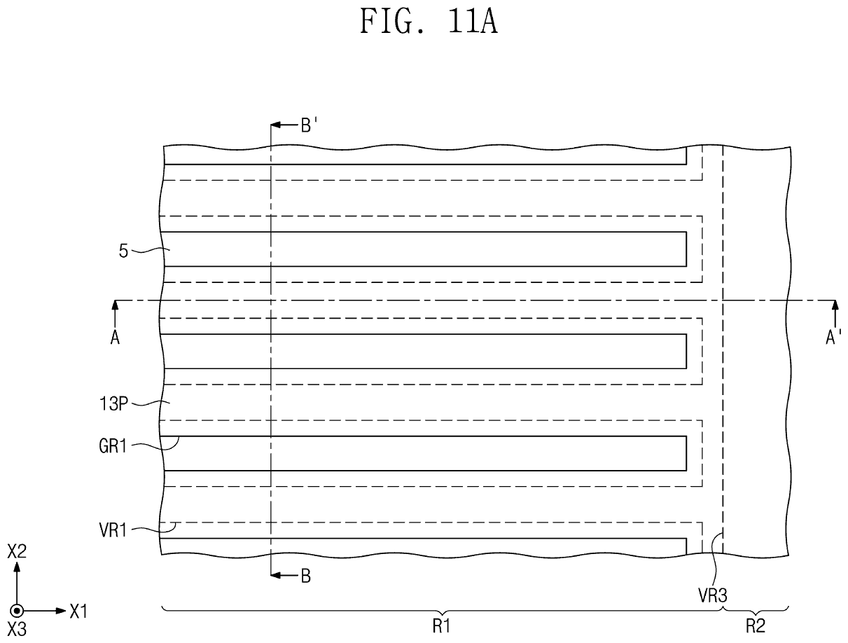

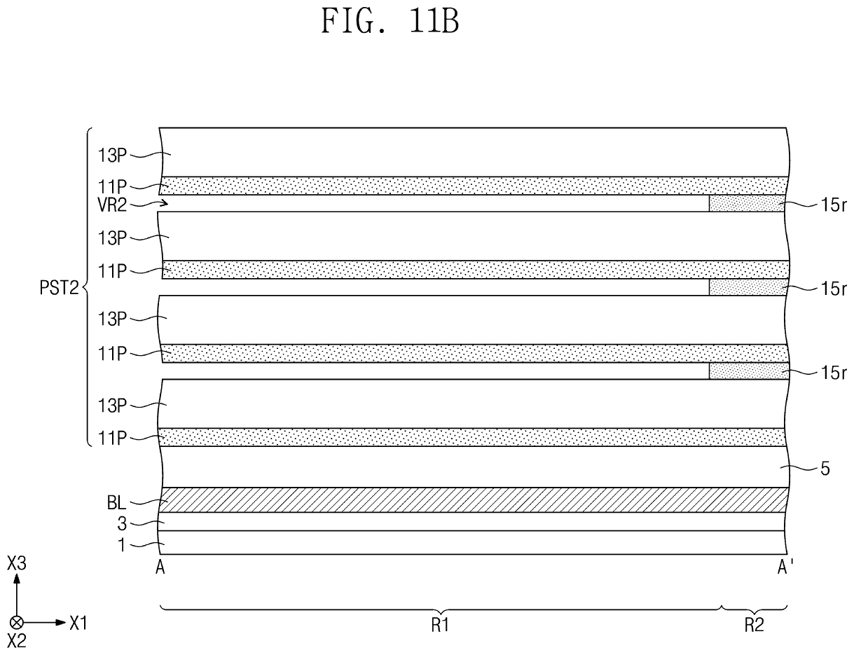

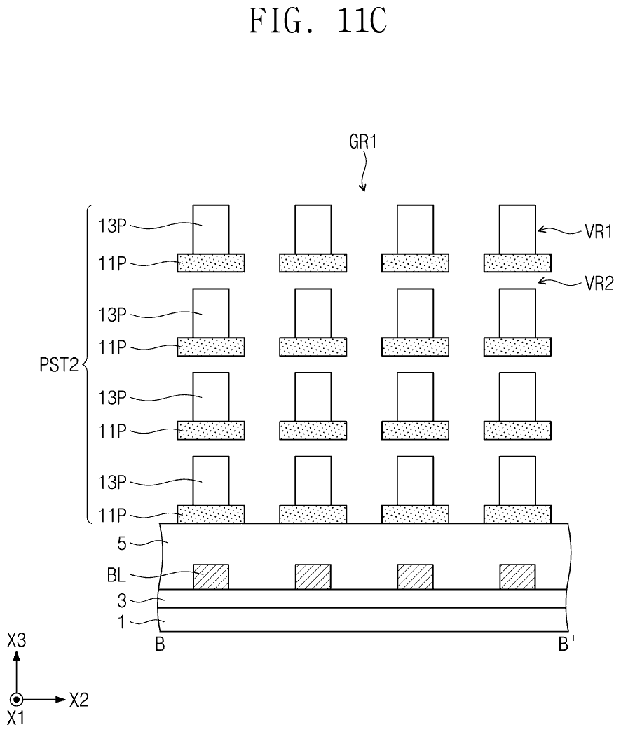

Referring to FIGS. 11A to 11C, an isotropic etching process is performed by supplying a second etchant through the first grooves GR1. Accordingly, second empty spaces VR2 are formed and third remaining sacrificial patterns 15r are left on the second region R2 by removing all of the third sacrificial patterns 15P of the second preliminary stack structure PST2 on the first region R1. The third remaining sacrificial patterns 15r may be portions of the third sacrificial patterns 15P. Since the third remaining sacrificial patterns 15r are in contact with the first and second sacrificial patterns 11P and 13P on the second region R2, although the second empty spaces VR2 are formed on the first region R1, the second preliminary stack structure PST2 may not be collapsed. Lower surfaces of the first sacrificial patterns 11P and upper surfaces of the second sacrificial patterns 13P may be exposed by the second empty spaces VR2.

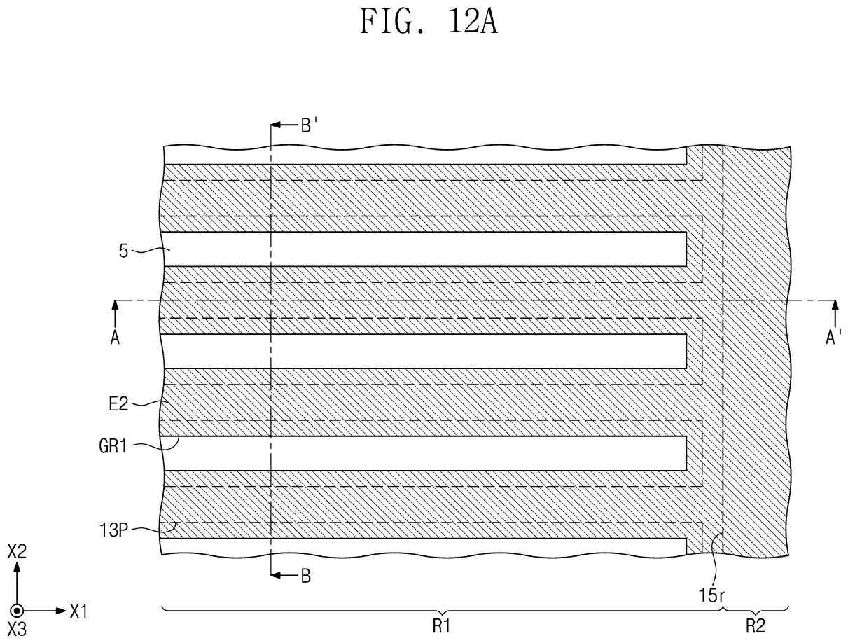

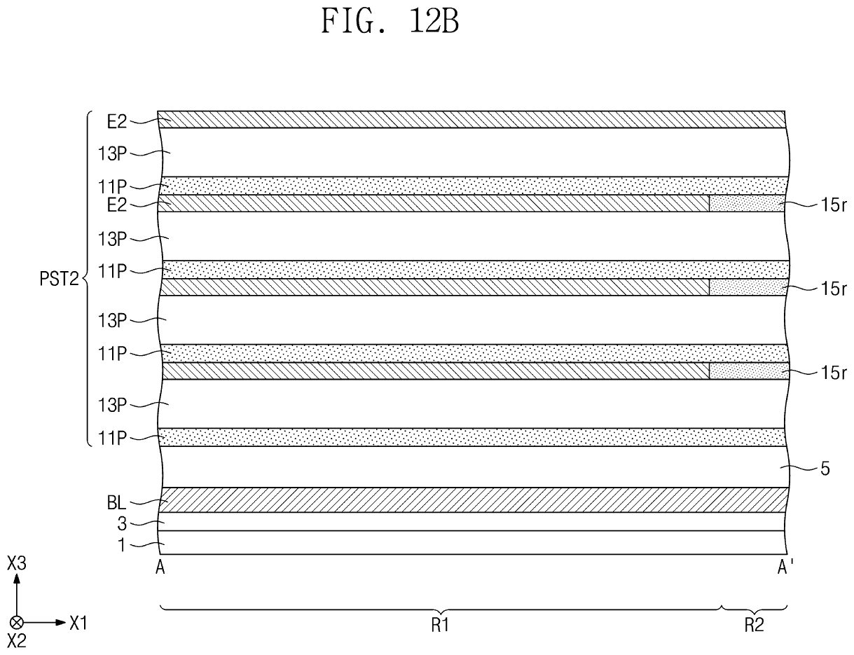

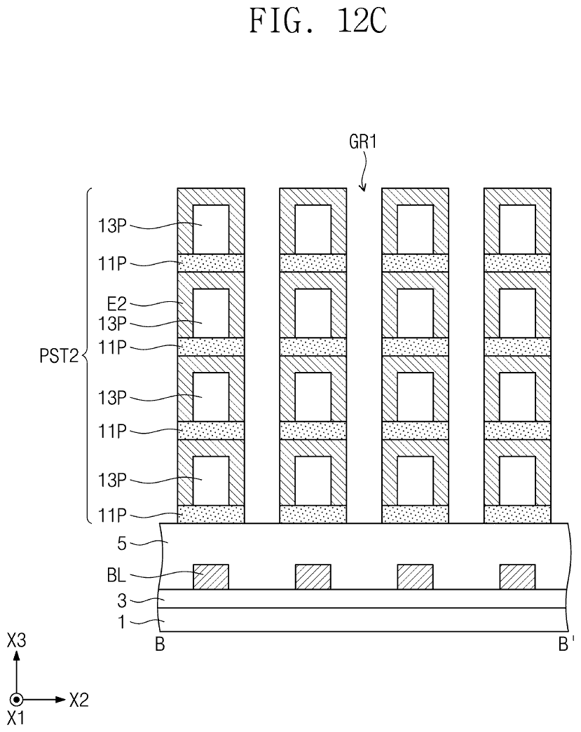

Referring to FIGS. 12A to 12C, the first empty spaces VR1, the second empty spaces VR2 and the first grooves GR1 are filled by stacking a conductive layer on the second preliminary stack structure PST2. In addition, the conductive layer in the first grooves GR1 is removed. Accordingly, second electrodes E2 that fill the first empty spaces VR1 and the second empty spaces VR2 may be formed. Each of the second electrodes E2 may cover an upper surface of the first sacrificial pattern 11P and an upper surface and a side surface of the second sacrificial pattern 13P. Side surfaces of the second electrodes E2 may be aligned with side surfaces of the first sacrificial patterns 11P. On a cross-section of FIG. 12B, the second electrodes E2 may be in contact with side surfaces of the third remaining sacrificial patterns 15r. The second electrode E2 may be formed so as to have the lower protrusions BP of FIG. 5A that fill the first empty spaces VR1.

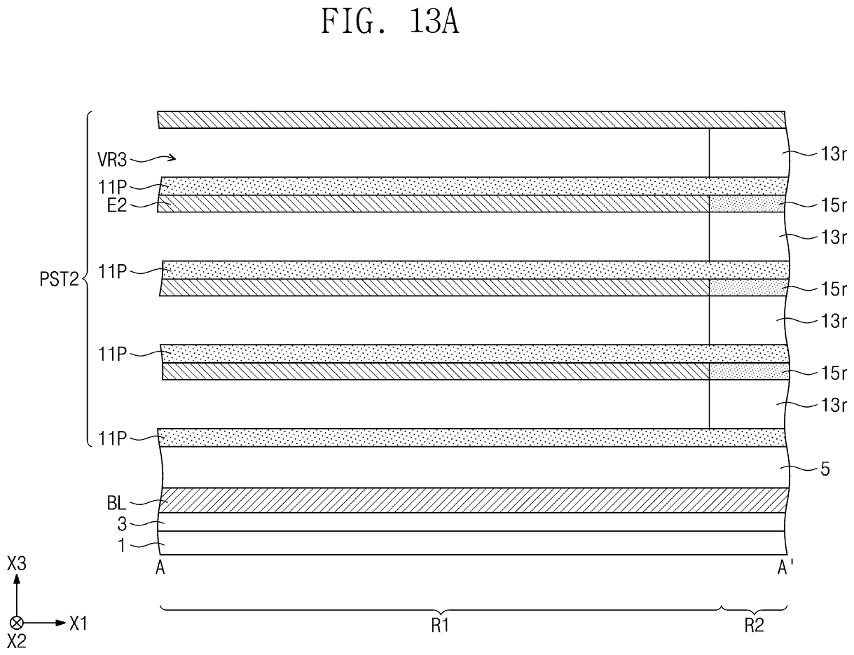

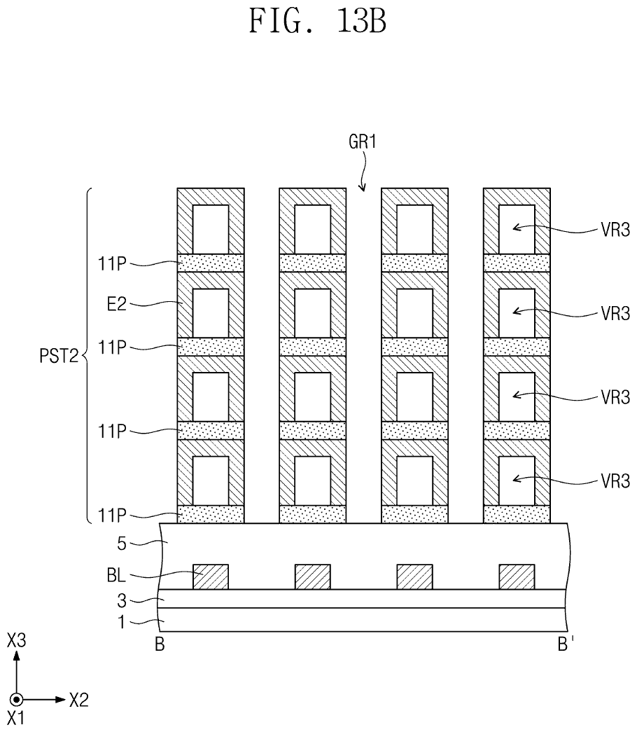

Referring to FIGS. 13A and 13B, an isotropic etching process is performed by supplying the first etchant through the first grooves GR1. Accordingly, third empty spaces VR3 are formed and second remaining sacrificial patterns 13r are left on the second region R2 by removing all of the second sacrificial patterns 13P of the second preliminary stack structure PST2 on the first region R1. The third empty spaces VR3 may be referred to as ‘hollow regions’. The second remaining sacrificial patterns 13r may be portions of the second sacrificial patterns 13P. The third empty spaces VR3 may expose inner side surfaces and inner upper surfaces of the second electrodes E2. Since the second remaining sacrificial patterns 13r are in contact with the third remaining sacrificial patterns 15r and the first sacrificial patterns 11P on the second region R2, although the third empty spaces VR3 are formed on the first region R1, the second preliminary stack structure PST2 may not be collapsed.

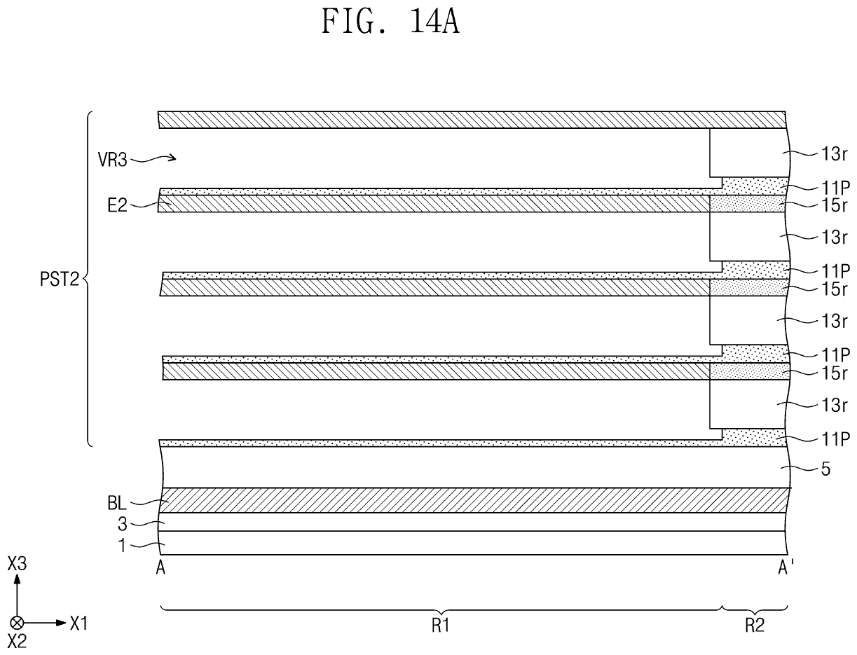

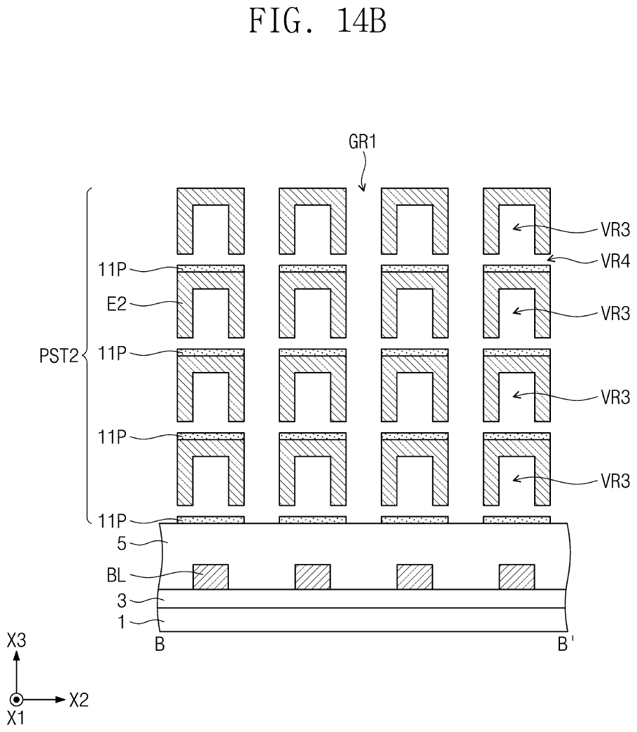

Referring to FIGS. 14A and 14B, an isotropic etching process is performed by supplying a third etchant through the first grooves GR1 to partially remove the first sacrificial patterns 11P. Accordingly, a thickness of the first sacrificial pattern 11P may be small on the first region R1. When seen on a cross-section of FIG. 14B, the first sacrificial pattern 11P is spaced apart from the second electrodes E2 to form fourth empty spaces VR4 between the second electrodes E2 and the first sacrificial pattern 11P. Lower surfaces of the second electrodes E2 and upper surfaces of the first sacrificial patterns 11P may be exposed by the fourth empty spaces VR4. A thickness of the first sacrificial pattern 11P may be small on the first region R1 to space the first sacrificial pattern 11P apart from the second electrodes E2. However, since the first sacrificial patterns 11P are in contact with the second remaining sacrificial patterns 13r and the third remaining sacrificial patterns 15r on the second region R2, the second preliminary stack structure PST2 may not be collapsed.

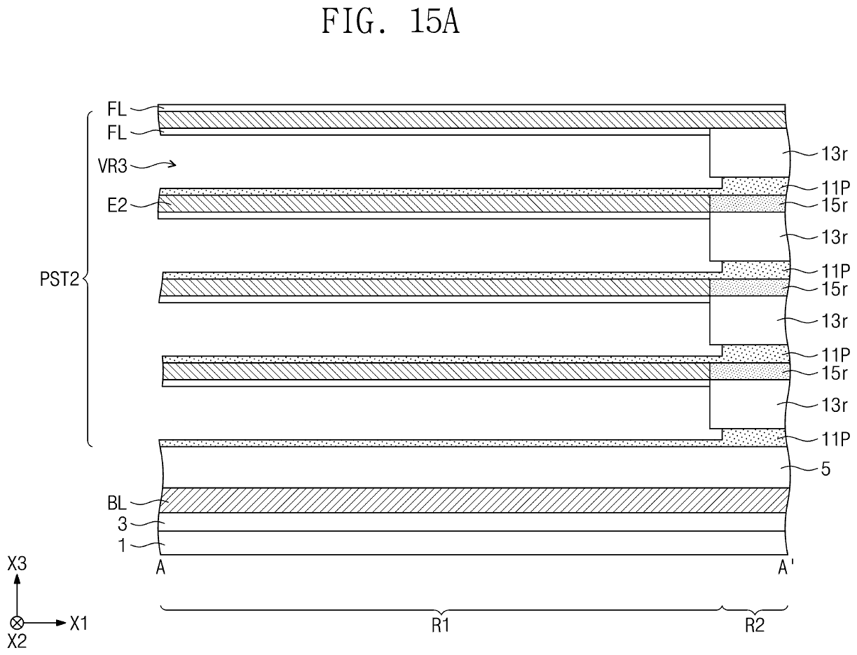

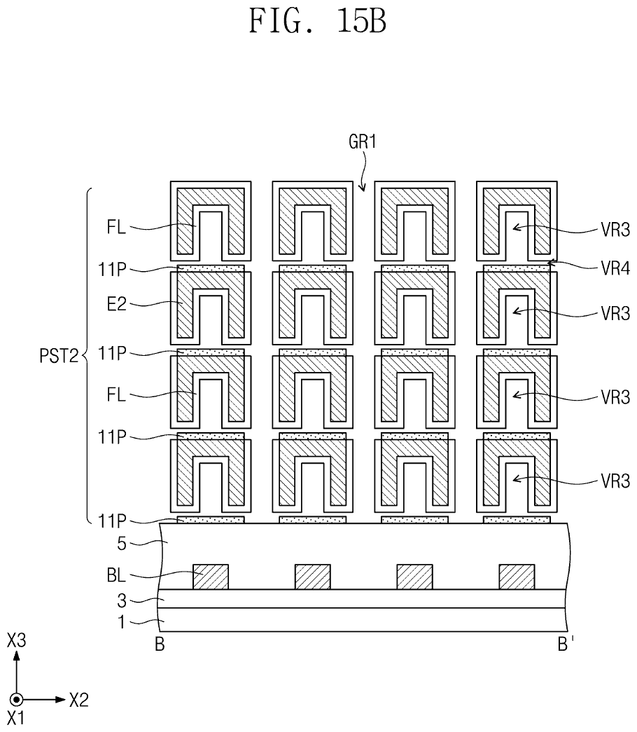

Referring to FIGS. 15A and 15B, a ferroelectric layer FL may be stacked on the second preliminary stack structure PST2. The ferroelectric layer FL may be formed in an area selective deposition method (or process). The ferroelectric layer FL is formed on surfaces of the second electrodes E2, but is not formed on surfaces of other components (that is, the first sacrificial patterns 11P, the second lower insulating layer 5 and the second remaining sacrificial patterns 13r). In the area selective deposition process, source gases for forming the ferroelectric layer FL may be adsorbed to the surfaces of the second electrodes E2 due to excellent affinity therewith, but may not be adsorbed to the surfaces of the other components (that is, the first sacrificial patterns 11P, the second lower insulating layer 5, and the second remaining sacrificial patterns 13r) due to low affinity therewith.

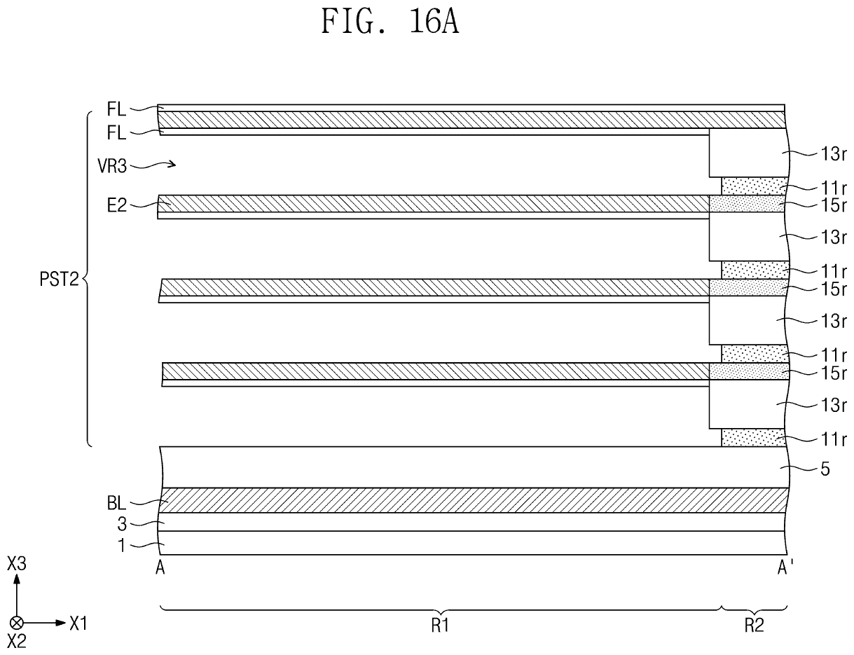

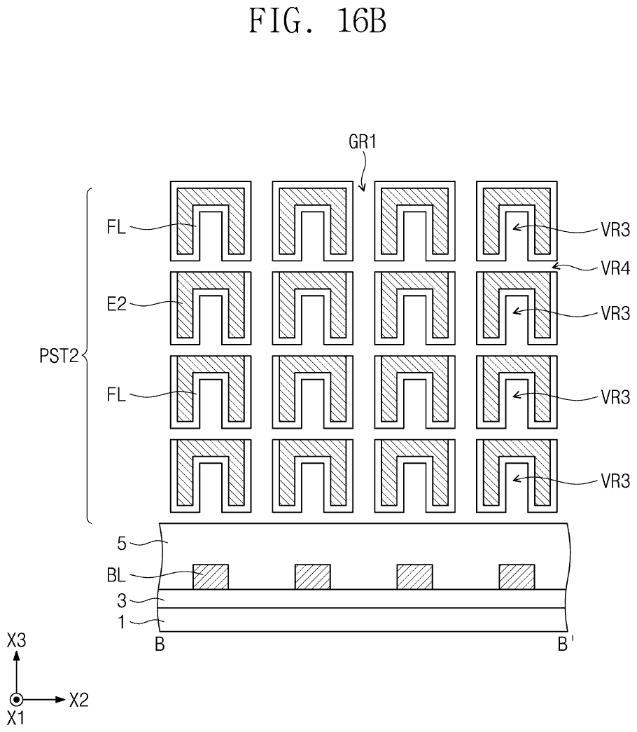

Referring to FIGS. 16A and 16B, the fourth empty spaces VR4 becomes wider, and first remaining sacrificial patterns 11r are left on the second region R2 by removing all of the first sacrificial patterns 11P on the first region R1 by performing an isotropic etching process by supplying the third etchant through the first grooves GR1. The first remaining sacrificial patterns 11r may be portions of the first sacrificial patterns 11P. The fourth empty spaces VR4 may expose upper surfaces of the second electrodes E2 and surfaces of the ferroelectric layers FL. Since the first remaining sacrificial patterns 11r are in contact with the second remaining sacrificial patterns 13r and the third remaining sacrificial patterns 15r on the second region R2, the second preliminary stack structure PST2 may not be collapsed.

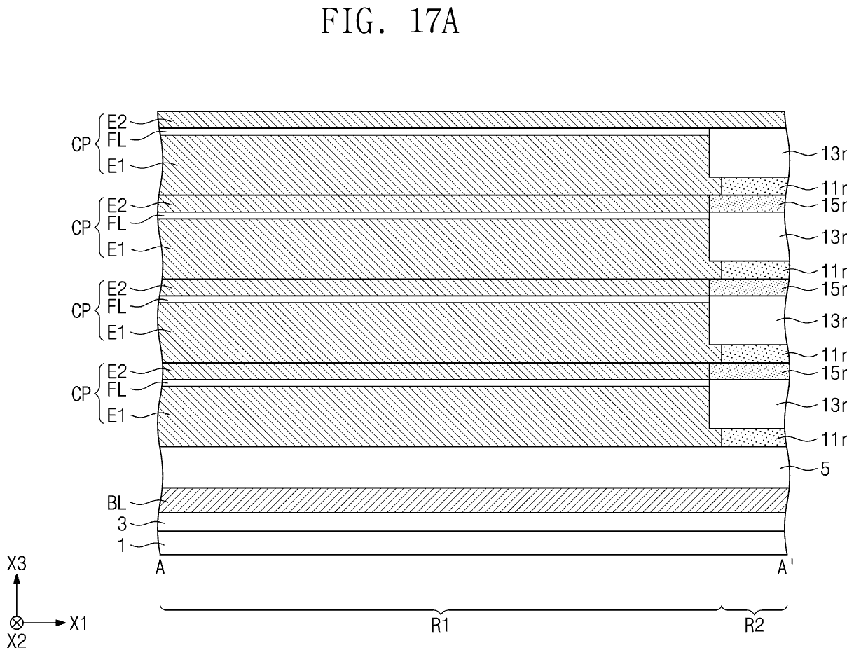

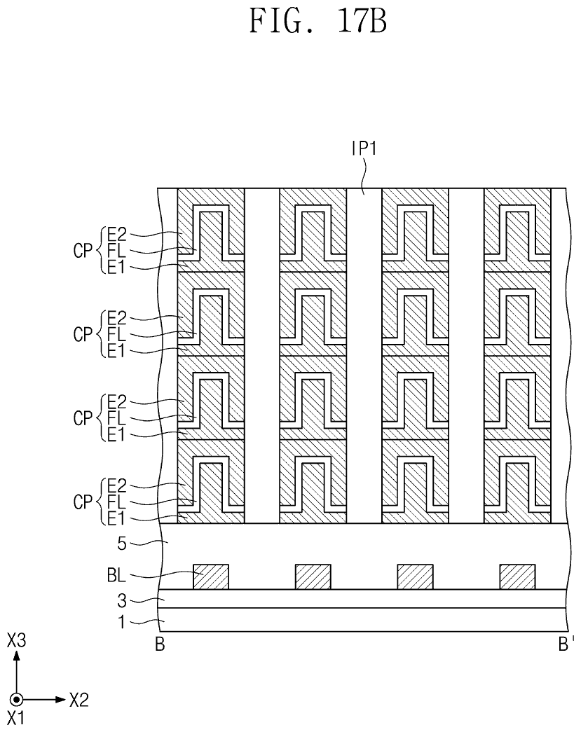

Referring to FIGS. 17A and 17B, the third empty spaces VR3, the fourth empty spaces VR4 and the first grooves GR1 are filled by stacking a conductive layer on the second preliminary stack structure PST2. The conductive layer and the ferroelectric layer FL on an uppermost second electrode E2 are removed. In addition, the conductive layer and the ferroelectric layer FL in the first grooves GR1 are removed. Accordingly, the first electrodes E1 may be formed. The ferroelectric layer FL may be left between the first electrodes E1 and the second electrode E2. The first electrodes E1 may be inserted into the third empty spaces VR3 and may be formed so as to have upper protrusions UP of FIG. 5A. The ferroelectric layer FL, the first electrode E1 and the second electrode E2 adjacent to each other may constitute one capacitor CP. The first separation insulating pattern IP1 is formed by filling the first grooves GR1 with an insulating material.

A cross-section taken along line B-B′ of FIG. 18A may be the same as FIG. 17B. Referring to FIGS. 17B, 18A and 18B, the second separation insulating pattern IP2 is formed by forming a trench exposing an upper portion of the second lower insulating layer 5 by partially removing the first to third remaining sacrificial patterns 11r, 13r and 15r and the first and second electrodes E1 and E2 on the second region R2, and then filling the trench with an insulating material. Accordingly, the capacitors CP of the ferroelectric memory device according to the present disclosure may be formed.

Since the capacitors CP are formed so as to have the protrusions UP and BP like the method above, electrical characteristics of the ferroelectric memory device may be improved by increasing capacitance.

Since electrodes of capacitors have protrusions in a ferroelectric memory device according to the present disclosure, capacitance of the capacitors may increase. In addition, since a thickness of a ferroelectric layer is smaller than a thickness of a word line, an operation voltage may be reduced. Accordingly, electrical characteristics of the ferroelectric memory device may be improved.

The capacitors including electrodes having an irregularity structure may be manufactured by using a method for manufacturing a ferroelectric memory device according to the present disclosure.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A ferroelectric memory device comprising:
a substrate; and
capacitors stacked on the substrate,
wherein each of the capacitors includes
a first electrode,
a ferroelectric layer on the first electrode, and
a second electrode on the ferroelectric layer,
wherein the first electrode includes a flat portion and an upper protrusion portion on the flat portion,
wherein the flat portion has a first width in a first direction parallel to an upper surface of the substrate, and
wherein the upper protrusion portion has a second width smaller than the first width in the first direction.

2. The ferroelectric memory device of claim 1, wherein the ferroelectric layer covers (i) an upper surface of the flat portion, and (ii) a side surface and an upper surface of the upper protrusion portion, and
wherein the second electrode covers an upper surface and a side surface of the ferroelectric layer.

3. The ferroelectric memory device of claim 1, wherein the capacitors comprise a first capacitor and a second capacitor on the first capacitor, and
wherein the second electrode of the first capacitor is in contact with the first electrode of the second capacitor.

4. The ferroelectric memory device of claim 1, further comprising:
an active pattern extending in a second direction perpendicular to the upper surface of the substrate;
word lines adjacent to first side surfaces of the active pattern, the word lines extending in the first direction and being spaced apart from one another in the second direction; and
gate insulating layers between the active pattern and the word lines,
wherein the first electrodes of the capacitors are respectively connected to second side surfaces of the active pattern.

5. The ferroelectric memory device of claim 4, wherein each of the word lines surrounds a respective first side surface of the first side surfaces of the active pattern.

6. The ferroelectric memory device of claim 4, comprising a selection line between the substrate and a lowermost word line of the word lines,
wherein the selection line extends in the first direction and is adjacent to a third side surface of the active pattern.

7. The ferroelectric memory device of claim 4, comprising a bit line between the active pattern and the substrate, the bit line being connected to a lower end of the active pattern,
wherein the bit line extends in a third direction parallel to the upper surface of the substrate, the third direction being different from the first direction.

8. The ferroelectric memory device of claim 4, comprising a bit line between the active pattern and the substrate, the bit line being connected to a lower end of the active pattern,
wherein the bit line extends in the first direction and is parallel to the word lines.

9. The ferroelectric memory device of claim 4, wherein each of the word lines has a first thickness, and
the ferroelectric layer has a second thickness smaller than the first thickness.

10. The ferroelectric memory device of claim 1, wherein the first electrode or the second electrode has a third width in a third direction parallel to the upper surface of the substrate, the third direction being different from the first direction, and
the third width is greater than the first width.

11. The ferroelectric memory device of claim 1, further comprising a plate line connected to the second electrode of an uppermost capacitor of the capacitors,
wherein the plate line extends either in the first direction or in a third direction, the third direction being different from the first direction and parallel to the upper surface of the substrate.

12. The ferroelectric memory device of claim 1, wherein the first electrode comprises a plurality of upper protrusion portions including the upper protrusion portion.

13. A ferroelectric memory device comprising:
a substrate;
a first electrode on the substrate;
a first ferroelectric layer on the first electrode;
second electrodes and second ferroelectric layers stacked on the first ferroelectric layer in an alternative manner; and
a third electrode on an uppermost second ferroelectric layer of the second ferroelectric layers,
wherein the first electrode includes a first upper protrusion portion and a first flat portion,
wherein each of the second electrodes includes
a second flat portion,
a second upper protrusion portion protruding from a center of the second flat portion along an upward direction, and
second lower protrusion portions protruding from edges of the second flat portion along a downward direction, and
wherein the third electrode includes a third flat portion and third lower protrusion portions.

14. The ferroelectric memory device of claim 13, wherein each of the first, second and third flat portions has a first width in a first direction parallel to an upper surface of the substrate,
wherein each of the first and second upper protrusion portions has a second width smaller than the first width in the first direction,
wherein each of the second and third lower protrusion portions have a third width smaller than the first width in the first direction,
wherein each of (i) the first and second flat portions, (ii) the first and second upper protrusion portions, and (iii) the second and third lower protrusion portions have a fourth width in a second direction parallel to the upper surface of the substrate, the second direction being different from the first direction, and
wherein the fourth width is greater than the first width.

15. The ferroelectric memory device of claim 14, further comprising:
an active pattern extending in a third direction perpendicular to the upper surface of the substrate;
word lines adjacent to first side surfaces of the active pattern, the word lines extending in the first direction and spaced apart from one another in the third direction; and
gate insulating layers between the active pattern and the word lines,
wherein each of the first, second and third electrodes is connected to a respective second side surface of second side surfaces of the active pattern.

16. The ferroelectric memory device of claim 15, wherein each of the word lines has a first thickness, and
each of the first ferroelectric layer and the second ferroelectric layers has a second thickness smaller than the first thickness.

17. The ferroelectric memory device of claim 15, further comprising a bit line between the active pattern and the substrate, the bit line being connected to a lower end of the active pattern,
wherein the bit line extends in the second direction.

18. The ferroelectric memory device of claim 13,
wherein the first electrode includes a plurality of first upper protrusion portions including the first upper protrusion portion, and
wherein each of the second electrodes includes a plurality of second upper protrusion portions including the second upper protrusion portion.

19. A ferroelectric memory device comprising:
a substrate;
bit lines on the substrate and extending in a first direction parallel to an upper surface of the substrate;
an active pattern connected to a bit line of the bit lines and extending along a second direction perpendicular to the upper surface of the substrate;
a selection line adjacent to a lower side surface of the active pattern and extending in a third direction, the third direction being parallel to the upper surface of the substrate and different from the first direction;
word lines stacked on the selection line and adjacent to upper side surfaces of the active pattern;
capacitors stacked on the substrate and on a side of the active pattern; and
a plate line in contact with an upper surface of an uppermost capacitor of the capacitors,
wherein each of the capacitors includes
a first electrode,
a ferroelectric layer on the first electrode, and
a second electrode on the ferroelectric layer, and
wherein the first electrode includes a flat portion and at least one upper protrusion portion protruding from the flat portion.

20. The ferroelectric memory device of claim 19, wherein the first electrode includes a plurality of upper protrusion portions including the at least one upper protrusion portion.
